(19) United States
(12) Patent Application Publication
(10) Pub. No.: US 2025/0359469 A1
(43) Pub. Date: Nov. 20, 2025

(54) DISPLAY PANEL AND DISPLAY SYSTEM INCLUDING THE SAME

(71) Applicant: Samsung Display Co., LTD., Yongin-si (KR)

(72) Inventor: Kyung Man KIM, Yongin-si (KR)

(21) Appl. No.: 19/022,881

(22) Filed: Jan. 15, 2025

(30) Foreign Application Priority Data
May 14, 2024 (KR) 10-2024-0062877

(51) Int. Cl. H10K 59/80

(52) U.S. Cl. CPC H10K 59/879; H10K 59/878

(57) ABSTRACT

In an embodiment of the present disclosure, provided is display panel including: a substrate; a pixel structure layer on the substrate, and including a plurality of sub-pixels; and a light path conversion unit on the pixel structure layer, and to convert a path of light generated from the pixel structure layer.

### CROSS-REFERENCE TO RELATED APPLICATION

The present application claims priority to and the benefit of Korean Patent Application No. 10-2024-0062877, filed on May 14, 2024, in the Korean Intellectual Property Office, the entire disclosure of which is incorporated by reference herein.

### BACKGROUND

### 1. Field

Aspects of embodiments of the present disclosure relate to a display panel, and a display system including the display panel.

### 2. Description of the Related Art

As information technology develops, the importance of a display device, which is a connection medium between a user and information, is emerging. As such, the use of a display device, such as a liquid crystal display device and an organic light emitting display device, is increasing.

A display system may include at least one display device. An image output from a display panel included in the display device may be displayed to a user through a lens.

The above information disclosed in this Background section is for enhancement of understanding of the background of the present disclosure, and therefore, it may contain information that does not constitute prior art.

### SUMMARY

Embodiments of the present disclosure may be directed to a display panel capable of reducing a size and a weight of a display system, and a display system including the display panel.

According to one or more embodiments of the present disclosure, a display panel includes: a substrate; a pixel structure layer on the substrate, and including a plurality of sub-pixels; and a light path conversion unit on the pixel structure layer, and configured to convert a path of light generated from the pixel structure layer.

In an embodiment, the light path conversion unit may be configured to converge the light generated from the pixel structure layer.

In an embodiment, the light path conversion unit may include a Fresnel lens on the pixel structure layer.

In an embodiment, the Fresnel lens may include an epoxy resin.

In an embodiment, the light path conversion unit may include a spherical lens or an aspherical lens on the pixel structure layer.

In an embodiment, the light path conversion unit may be configured to change a progress direction of the light generated from the pixel structure layer.

In an embodiment, the light path conversion unit may include a reflective layer.

In an embodiment, the reflective layer may have a flat surface.

In an embodiment, the reflective layer may have a curved surface.

In an embodiment, the display panel may further include a protective layer on the light path conversion unit.

In an embodiment, the display panel may further include a cover window between the pixel structure layer and the light path conversion unit.

In an embodiment, the display panel may further include a polarizing film layer between the cover window and the light path conversion unit.

In an embodiment, the display panel may further include a wire grid polarizing layer between the pixel structure layer and the light path conversion unit.

In an embodiment, the display panel may further include a dam surrounding the pixel structure layer.

In an embodiment, the pixel structure layer may include: a pixel circuit layer on the substrate; a light emitting element layer on the pixel circuit layer; and an optical functional layer on the light emitting element layer.

In an embodiment, the pixel circuit layer may include at least one transistor; the light emitting element layer may include an anode electrode, a light emitting structure, and a cathode electrode; and the optical function layer may include a color filter layer and a lens array.

According to one or more embodiments of the present disclosure, a display system include: a receiving case; and at least one display panel in the receiving case, the at least one display panel including: a substrate; a pixel structure layer on the substrate, and including a plurality of sub-pixels; and a light path conversion unit on the pixel structure layer, and configured to convert a path of light generated from the pixel structure layer.

In an embodiment, the display system may further include at least one lens in the receiving case to receive light of which a path is changed by the light path conversion unit.

In an embodiment, the light path conversion unit may be configured to converge the light generated from the pixel structure layer.

In an embodiment, the light path conversion unit may include a Fresnel lens on the pixel structure layer.

In an embodiment, the light path conversion unit may include a spherical lens or an aspherical lens on the pixel structure layer.

In an embodiment, the light path conversion unit may be configured to change a progress direction of the light generated from the pixel structure layer.

In an embodiment, the light path conversion unit may include a reflective layer.

In an embodiment, the reflective layer may have a flat surface.

1 In an embodiment, the reflective layer may have a curved surface.

According to some embodiments of the present disclosure, a size and a weight of a display system including a display panel may be reduced.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a block diagram illustrating a display device, according to an embodiment;

FIG. 2 is a block diagram illustrating one sub-pixel of FIG. 1, according to an embodiment;

FIG. 3 is a plan view illustrating a display panel of FIG. 1, according to an embodiment;

FIG. 4 is an exploded perspective view illustrating a portion of the display panel of FIG. 3;

FIG. 5 is a plan view illustrating one pixel of FIG. 4, according to an embodiment;

FIG. 6 is a cross-sectional view taken along the line I-I′ of FIG. 5;

FIG. 7 is a cross-sectional view of a light emitting structure included in one light emitting element of FIG. 6, according to an embodiment;

FIG. 8 is a cross-sectional view of a light emitting structure included in one light emitting element of FIG. 6, according to an embodiment;

FIG. 9 is a plan view illustrating one pixel of FIG. 4, according to an embodiment;

FIG. 10 is a plan view illustrating one pixel of FIG. 4, according to an embodiment;

FIG. 11 is a block diagram illustrating a display system, according to an embodiment;

FIG. 12 is a perspective view illustrating an application example of the display system of FIG. 11;

FIG. 13 is a diagram illustrating a head mounted display device of FIG. 12 worn by a user;

FIG. 14 is a diagram illustrating a distance between a display panel shown in FIG. 13 and a user's eye;

FIG. 15 is a cross-sectional view illustrating a display panel of a display device, according to an embodiment;

FIG. 16 is a diagram illustrating a light path conversion unit of FIG. 15, according to an embodiment;

FIGS. 17A-17E are diagrams illustrating a method of manufacturing a display panel shown in FIG. 16;

FIGS. 18A-18C are diagrams illustrating a light path conversion unit of FIG. 15, according to one or more embodiments;

FIG. 19 is a diagram illustrating a light path conversion unit of FIG. 15, according to an embodiment;

FIGS. 20A and 20B are cross-sectional views illustrating a display panel of a display device, according to one or more embodiments;

FIG. 21 is a cross-sectional view illustrating a display panel of a display device, according to an embodiment;

FIG. 22 is a cross-sectional view illustrating a display panel of a display device, according to an embodiment;

FIG. 23 is a cross-sectional view illustrating a display panel of a display device, according to an embodiment; and

FIGS. 24A-24F are diagrams illustrating a method of manufacturing the display panel shown in FIG. 16, according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

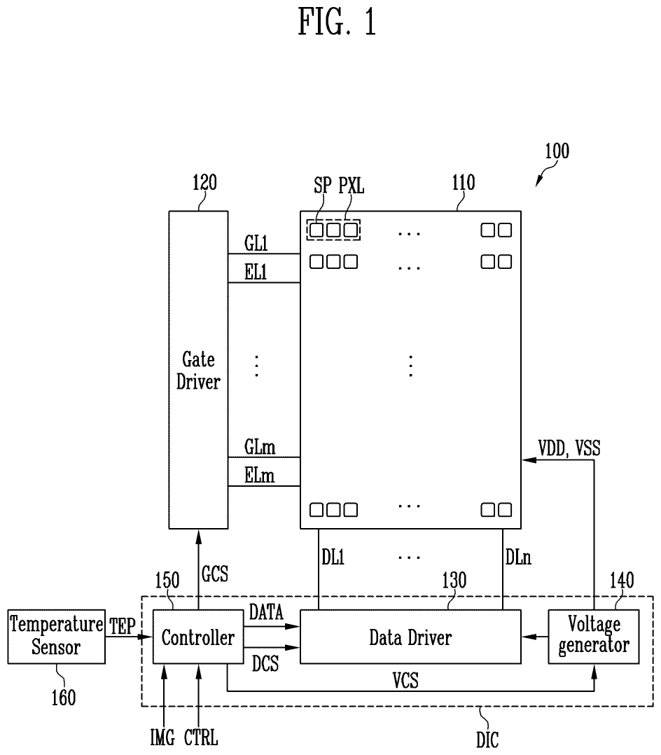

FIG. 1 is a block diagram illustrating a display device, according to an embodiment.

Referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm, where m is an integer. The sub-pixels SP may be connected to the data driver 130 through first to n-th data lines DL1 to DLn, where n is an integer.

Each of the sub-pixels SP may include at least one light emitting element to generate light. Accordingly, each of the sub-pixels SP may generate light of a desired color (e.g., a specific or predetermined color), such as red, green, blue, cyan, magenta, or yellow. Two or more sub-pixels from among the sub-pixels SP may configure one pixel PXL. For example, as shown in FIG. 1, three sub-pixels may configure one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In some embodiments, the gate control signal GCS may include a start signal indicating a start of each frame, a horizontal synchronization signal for outputting the gate signals in synchronization with a timing at which data signals are applied, and the like.

In some embodiments, first to m-th emission control lines EL1 to ELm connected to the sub-pixels SP of the row direction may be further provided. In this case, the gate driver 120 may include an emission control driver to control the first to m-th emission control lines EL1 to ELm, and the emission control driver may operate under the control of the controller 150.

The gate driver 120 may be disposed on one side of the display panel 110. However, the present disclosure is not limited thereto. For example, the gate driver 120 may be divided into two or more physically and/or logically divided drivers, and the drivers may be disposed on one side of the display panel 110 and another side of the display panel 110 opposite the one side. As described above, the gate driver 120 may be disposed around the display panel 110 in various suitable shapes as needed or desired.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In some embodiments, the data control signal DCS may include a source start pulse, a source shift clock, a source output enable signal, and the like.

The data driver 130 may apply the data signals having grayscale voltages (e.g., grayscale levels or values) corresponding to the image data DATA to the first to n-th data lines DL1 to DLn using voltages from the voltage generator 140. When the gate signal is applied to each of the first to m-th gate lines GL1 to GLm, the data signals corresponding to the image data DATA may be applied to the data lines DL1 to DLm. Accordingly, the selected sub-pixels SP may generate light corresponding to the data signals. Accordingly, an image may be displayed on the display panel 110.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate a plurality of voltages, and may provide the generated voltages to the components of the display device 100. For example, the voltage generator 140 may generate the plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than that of the first power voltage VDD. In other embodiments, the first power voltage VDD or the second power voltage VSS may be provided by an external device of the display device 100.

In addition, the voltage generator 140 may generate various suitable voltages. For example, the voltage generator 140 may generate an initialization voltage applied to the sub-pixels SP. For example, during a sensing operation for sensing electrical characteristics of transistors and/or light emitting elements of the sub-pixels SP, a reference voltage (e.g., a predetermined reference voltage) may be applied to the first to n-th data lines DL1 to DLn, and the voltage generator 140 may generate the reference voltage.

The controller 150 controls the overall operations of the display device 100. The controller 150 receives input image data IMG and a control signal CTRL for controlling a display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110, and may output the image data DATA. In some embodiments, the controller 150 may output the image data DATA by aligning the input image data IMG, so that the input image data IMG is suitable for the sub-pixels SP in a unit of a row (e.g., in a row unit).

Two or more components from among the data driver 130, the voltage generator 140, and/or the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In other embodiments, at least one of the data driver 130, the voltage generator 140, or the controller 150 may be provided as a component distinguished from (e.g., as a separate component from) the driver integrated circuit DIC.

The display device 100 may include at least one temperature sensor 160. The temperature sensor 160 may sense a temperature around the temperature sensor 160, and may generate temperature data TEP indicating the sensed temperature. In some embodiments, the temperature sensor 160 may be disposed adjacent to the display panel 110 and/or adjacent to the driver integrated circuit DIC.

The controller 150 may control various operations of the display device 100 in response to the temperature data TEP. In some embodiments, the controller 150 may adjust a luminance of the image output from the display panel 110 in response to the temperature data TEP. For example, the controller 150 may control the data signals and the first and second power voltages VDD and VSS by controlling the components, such as the data driver 130 and/or the voltage generator 140.

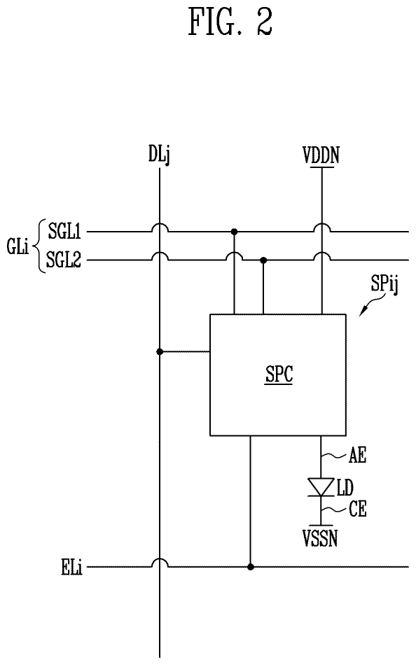

FIG. 2 is a block diagram illustrating one sub-pixel of FIG. 1, according to an embodiment. In FIG. 2, from among the sub-pixels SP described above with reference to FIG. 1, one sub-pixel SPij arranged in an i-th row (where i is an integer greater than or equal to 1 and less than or equal to m) and a j-th column (where j is an integer greater than or equal to 1 and less than or equal to n) is shown as a representative example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node that transfers the first power voltage VDD described above with reference to FIG. 1, and the second power voltage node VSSN may be a node that transfers the second power voltage VSS.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi from among the first to m-th gate lines GL1 to GLm described above with reference to FIG. 1, an i-th emission control line ELi from among the first to m-th emission control lines EL1 to ELm, and a j-th data line DLj from among the first to n-th data lines DL1 to DLn. The sub-pixel circuit SPC may control the light emitting element LD according to signals received through the signal lines.

The sub-pixel circuit SPC may operate in response to a gate signal received through the i-th gate line GLi. The i-th gate line GLi may include one or more sub-gate lines. In some embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As described above, when the i-th gate line GLi includes two or more sub-gate lines, the sub-pixel circuit SPC may operate in response to gate signals received through the corresponding two or more sub-gate lines.

The sub-pixel circuit SPC may operate in response to an emission control signal received through the i-th emission control line ELi. In some embodiments, the i-th emission control line ELi may include one or more sub-emission control lines. When the i-th emission control line ELi includes two or more sub-emission control lines, the sub-pixel circuit SPC may operate in response to emission control signals received through the corresponding two or more sub-emission control lines.

The sub-pixel circuit SPC may receive a data signal through the j-th data line DLj. The sub-pixel circuit SPC may store a voltage corresponding to the data signal in response to at least one of the gate signals received through the first or second sub-gate lines SGL1 or SGL2. The sub-pixel circuit SPC may adjust a current flowing from the first power voltage node VDDN to the second power voltage node VSSN through the light emitting element LD according to the stored voltage, in response the emission control signal received through the i-th emission control line ELi. Accordingly, the light emitting element LD may generate light having a luminance corresponding to the data signal.

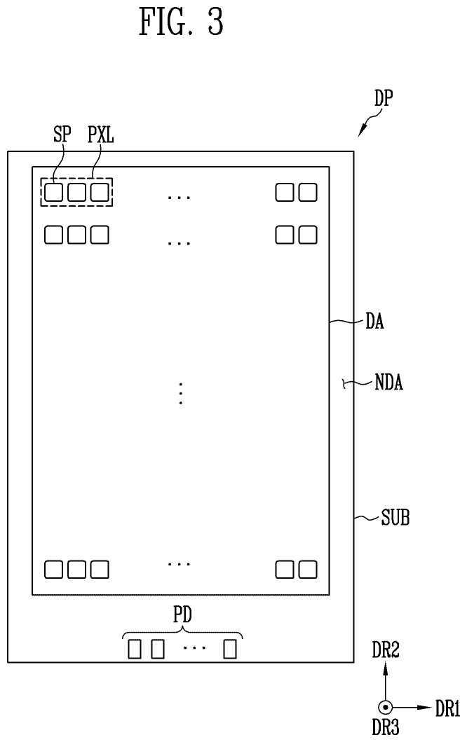

FIG. 3 is a plan view illustrating a display panel of FIG. 1, according to an embodiment.

Referring to FIG. 3, a display panel DP corresponding to the display panel 110 of FIG. 1 may include a display area DA and a non-display area NDA. The display panel DP displays an image through the display area DA. The non-display area NDA is disposed around the display area DA.

The display panel DP may include a substrate SUB, the sub-pixels SP, and pads PD.

When the display panel DP is used as a display screen of a head mounted display (HMD), a virtual reality (VR) device, a mixed reality (MR) device, an augmented reality (AR) device, or the like, the display panel DP may be positioned close (e.g., very close) to user's eyes. In this case, the sub-pixels SP may have a relatively high integration degree. In order to increase the integration degree of the sub-pixels SP, the substrate SUB may be provided as a silicon substrate. The sub-pixels SP and/or the display panel DP may be formed on the substrate SUB, which may be the silicon substrate. The display device 100 (e.g., refer to FIG. 1) including the display panel DP formed on the substrate SUB, which is the silicon substrate, may be referred to as an OLED on silicon (OLEDoS) display device.

The sub-pixels SP are disposed in the display area DA on the substrate SUB. The sub-pixels SP may be arranged in a matrix shape along a first direction DR1, and a second direction DR2 crossing the first direction DR1. However, the present disclosure is not limited thereto. For example, the sub-pixels SP may be arranged in a zigzag shape along the first direction DR1 and the second direction DR2. For example, the sub-pixels SP may be arranged in a diamond shape (e.g., a PENTILE® shape, PENTILE® being a duly registered trademark of Samsung Display Co., Ltd.). The first direction DR1 may be a row direction, and the second direction DR2 may be a column direction.

Two or more sub-pixels from among the plurality of sub-pixels SP may configure one pixel PXL.

A component for controlling the sub-pixels SP may be disposed in the non-display area NDA on the substrate SUB. For example, lines connected to the sub-pixels SP, such as the first to m-th gate lines GL1 to GLm and the first to n-th data lines DL1 to DLn described above with reference to FIG. 1, may be disposed in the non-display area NDA.

At least one of the gate driver 120, the data driver 130, the voltage generator 140, the controller 150, and/or the temperature sensor 160 described above with reference to FIG. 1 may be integrated in the non-display area NDA of the display panel DP. In some embodiments, the gate driver 120 described above with reference to FIG. 1 may be mounted on the display panel DP, and may be disposed in the non-display area NDA. In other embodiments, the gate driver 120 may be implemented as an integrated circuit separated from the display panel DP. In some embodiments, the temperature sensor 160 may be disposed in the non-display area NDA to sense a temperature of the display panel DP.

The pads PD are disposed in the non-display area NDA on the substrate SUB. The pads PD may be electrically connected to the sub-pixels SP through the lines. For example, the pads PD may be connected to the sub-pixels SP through the first to n-th data lines DL1 to DLn.

The pads PD may interface the display panel DP to other components of the display device 100 (e.g., refer to FIG. 1). In some embodiments, voltages and signals used for an operation of the components included in the display panel DP may be provided from the driver integrated circuit DIC described above with reference to FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In some embodiments, a circuit board may be electrically connected to the pads PD using a conductive adhesive member, such as an anisotropic conductive film. The circuit board may be a flexible circuit board (FPCB) or a flexible film having a flexible material. The driver integrated circuit DIC may be mounted on the circuit board to be electrically connected to the pads PD.

In some embodiments, the display area DA may have various suitable shapes. The display area DA may have a closed loop shape including straight sides and/or curved sides. For example, the display area DA may have various suitable shapes, such as a polygon, a circle, a semicircle, and an ellipse.

In some embodiments, the display panel DP may have a flat or substantially flat display surface. In other embodiments, the display panel DP may have a display surface that is at least partially rounded. In some embodiments, the display panel DP may be bendable, foldable, or rollable. In this case, the display panel DP and/or the substrate SUB may include suitable materials having a flexible property.

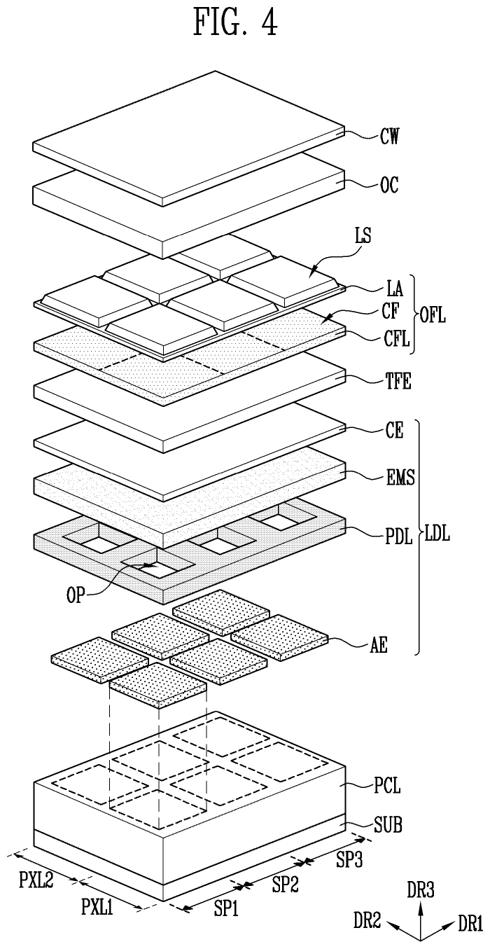

FIG. 4 is an exploded perspective view illustrating a portion of the display panel of FIG. 3. In FIG. 4, for convenience of illustration, a portion of the display panel DP corresponding to two pixels PXL1 and PXL2 from among the pixels PXL described above with reference to FIG. 3 is schematically shown. A portion of the display panel DP corresponding to the other remaining pixels PXL may be configured the same or substantially the same as (or similarly to) that illustrated in FIG. 4.

Referring to FIGS. 3 and 4, each of the first and second pixels PXL1 and PXL2 may include first to third sub-pixels SP1, SP2, and SP3. However, the present disclosure is not limited thereto. For example, each of the first and second pixels PXL1 and PXL2 may include four sub-pixels, or may include two sub-pixels.

In FIG. 4, the first to third sub-pixels SP1, SP2, and SP3 have quadrangle shapes when viewed from a third direction DR3 (e.g., in a plan view) crossing the first and second directions DR1 and DR2, and have sizes equal to or substantially equal to each other. However, the present disclosure is not limited thereto. In other embodiments, the first to third sub-pixels SP1, SP2, and SP3 may have various suitable shapes.

The display panel DP may include the substrate SUB, a pixel circuit layer PCL, a light emitting element layer LDL, an encapsulation layer TFE, an optical functional layer OFL, an overcoat layer OC, and a cover window CW.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In other embodiments, the substrate SUB may include a polyimide (PI) substrate.

The pixel circuit layer PCL is disposed on the substrate SUB. The substrate SUB and/or the pixel circuit layer PCL may include insulating layers, and conductive patterns disposed between the insulating layers. The conductive patterns of the pixel circuit layer PCL may function as at least a portion of the circuit elements, the lines, and the like. The conductive patterns may include copper, but the present disclosure is not limited thereto.

The circuit elements may include the sub-pixel circuit SPC (e.g., refer to FIG. 2) for each of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping with the semiconductor portion. In some embodiments, when the substrate SUB is provided as a silicon substrate, the semiconductor portion may be included in the substrate SUB, and the gate electrode may be included in the pixel circuit layer PCL as a conductive pattern of the pixel circuit layer PCL. In some embodiments, when the substrate SUB is provided as a glass substrate or a PI substrate, the semiconductor portion and the gate electrode may be included in the pixel circuit layer PCL. Each capacitor may include electrodes that are spaced apart from each other. For example, each capacitor may include electrodes that are spaced apart from each other on a plane defined by the first and second directions DR1 and DR2. For example, each capacitor may include electrodes that are spaced apart from each other in the third direction DR3, with an insulating layer interposed therebetween.

The lines of the pixel circuit layer PCL may include signal lines connected to each of the first to third sub-pixels SP1, SP2, and SP3, for example, such as a gate line, an emission control line, a data line, and the like. The lines may further include a line connected to the first power voltage node VDDN described above with reference to FIG. 2. In addition, the lines may further include a line connected to the second power voltage node VSSN described above with reference to FIG. 2.

The light emitting element layer LDL may include the anode electrodes AE, a pixel defining layer PDL, a light emitting structure EMS, and the cathode electrode CE.

The anode electrodes AE may be disposed on the pixel circuit layer PCL. The anode electrodes AE may contact the circuit elements of the pixel circuit layer PCL. The anode electrodes AE may include an opaque conductive material capable of reflecting light, but the present disclosure is not limited thereto.

The pixel defining layer PDL is disposed on the anode electrodes AE. The pixel defining layer PDL may include an opening OP exposing a portion of each of the anode electrodes AE. The opening OP of the pixel defining layer PDL may be understood as emission areas corresponding to the first to third sub-pixels SP1 to SP3, respectively.

In some embodiments, the pixel defining layer PDL may include an inorganic material. In this case, the pixel defining layer PDL may include a plurality of stacked inorganic layers. For example, the pixel defining layer PDL may include silicon oxide SiOx and silicon nitride SiNx. In other embodiments, the pixel defining layer PDL may include an organic material. However, the material of the pixel defining layer PDL is not limited thereto.

The light emitting structure EMS may be disposed on the anode electrodes AE exposed by the opening OP of the pixel defining layer PDL. The light emitting structure EMS may include a light emitting layer to generate light, an electron transport layer to transport an electron, a hole transport layer to transport a hole, and the like.

In some embodiments, the light emitting structure EMS may fill the opening OP of the pixel defining layer PDL, and may be entirely disposed on the pixel defining layer PDL. In other words, the light emitting structure EMS may extend across the first to third sub-pixels SP1 to SP3. In this case, at least a portion of the layers in the light emitting structure EMS may be disconnected or bent at boundaries between the first to third sub-pixels SP1 to SP3. However, the present disclosure is not limited thereto. For example, portions of the light emitting structure EMS corresponding to the first to third sub-pixels SP1 to SP3 may be spaced apart (e.g., may be separated) from each other, and each of the portions may be disposed in a corresponding opening OP of the pixel defining layer PDL.

The cathode electrode CE may be disposed on the light emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness that is sufficient to transmit light emitted from the light emitting structure EMS. The cathode electrode CE may be formed of a metal material or a transparent conductive material to have a relatively thin thickness. In some embodiments, the cathode electrode CE may include at least one of various suitable transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), and/or a suitable mixture thereof. However, the material of the cathode electrode CE is not limited thereto.

One of the anode electrodes AE, a portion of the light emitting structure EMS overlapping with it, and a portion of the cathode electrode CE overlapping with it may configure one light emitting element LD (e.g., refer to FIG. 2). In other words, each of the light emitting elements of the first to third sub-pixels SP1 to SP3 may include one anode electrode AE, a portion of the light emitting structure EMS overlapping with the anode electrode AE, and a portion of the cathode electrode CE overlapping with the anode electrode AE. In each of the first to third sub-pixels SP1 to SP3, holes injected from the corresponding anode electrode AE and electrons injected from the cathode electrode CE may be transported into the light emitting layer of the light emitting structure EMS to form excitons, and when the excitons transit from an excited state to a ground state, light may be generated. A luminance of the light may be determined according to an amount of a current flowing through the light emitting layer. According to a configuration of the light emitting layer, a wavelength range of the generated light may be determined.

The encapsulation layer TFE is disposed on the cathode electrode CE. The encapsulation layer TFE may cover the light emitting element layer LDL and/or the pixel circuit layer PCL. The encapsulation layer TFE may prevent or substantially prevent oxygen, moisture, and/or the like from permeating to the light emitting element layer LDL. In some embodiments, the encapsulation layer TFE may include a structure in which one or more inorganic layers and one or more organic layers are alternately stacked. For example, the inorganic layer may include silicon nitride, silicon oxide, silicon oxynitride (SiOxNy), or the like. For example, the organic layer may include an organic insulating material, such as an acrylic resin (polyacrylatesacrylic resin), an epoxy resin, a phenolic resin, a polyamides resin, a polyimides resin, an unsaturated polyesters resin, a poly phenylenethers resin, polyphenylenesulfides resin, or benzocyclobutene (BCB). However, the materials of the organic layer and the inorganic layer of the encapsulation layer TFE are not limited thereto.

In order to improve an encapsulation efficiency of the encapsulation layer TFE, the encapsulation layer TFE may further include a thin film including aluminum oxide (AlOx). The thin film including the aluminum oxide may be positioned on an upper surface of the encapsulation layer TFE facing the optical functional layer OFL, and/or on a lower surface of the encapsulating layer TFE facing the light emitting element layer LDL.

The thin film including the aluminum oxide may be formed through an atomic layer deposition (ALD) method. However, the present disclosure is not limited thereto. The encapsulation layer TFE may further include a thin film formed of at least one of various materials suitable for improving the encapsulation efficiency.

The optical functional layer OFL is disposed on the encapsulation layer TFE. The optical functional layer OFL may include a color filter layer CFL and a lens array LA.

The color filter layer CFL is disposed between the encapsulation layer TFE and the lens array LA. The color filter layer CFL may filter the light emitted from the light emitting structure EMS, and may selectively output light of a wavelength range or a color corresponding to each sub-pixel SP. The color filter layer CFL may include color filters CF corresponding to the first to third sub-pixels SP1 to SP3, respectively, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light emitting structure EMS of each sub-pixel SP, at least a portion of the color filters CF may be omitted.

The lens array LA is disposed on the color filter layer CFL. The lens array LA may include lenses LS corresponding to the first to third sub-pixels SP1 to SP3, respectively. Each of the lenses LS may improve a light output efficiency by outputting the light emitted from the light emitting structure EMS to an intended path. The lens array LA may have a relatively high refractive index. For example, the lens array LA may have a refractive index higher than that of the overcoat layer OC. In some embodiments, the lenses LS may include an organic material. In some embodiments, the lenses LS may include an acrylic (acrylicacrylate) material. However, the material of the lenses LS is not limited thereto.

In some embodiments, compared to the opening OP of the pixel defining layer PDL, at least a portion of the color filters CF of the color filter layer CFL and at least a portion of the lenses LS of the lens array LA may be shifted in a direction parallel to or substantially parallel to the plane defined by the first and second directions DR1 and DR2. In more detail, in a central area of the display area DA, a center of the color filter CF and a center of the lens LS may be aligned with or may overlap with a center of the corresponding opening OP of the pixel definition layer PDL when viewed in the third direction DR3 (e.g., in a plan view). For example, in the central area of the display area DA, the opening OP of the pixel defining layer PDL may completely overlap with the corresponding color filter CF of the color filter layer CFL and the corresponding lens LS of the lens array LA. In an area adjacent to the non-display area NDA in the display area DA, the center of the color filter CF and the center of the lens LS may be shifted in a plane direction from the center of the opening OP of the corresponding pixel defining layer PDL when viewed in the third direction DR3. For example, in the area adjacent to the non-display area NDA in the display area DA, the opening OP of the pixel defining layer PDL may partially overlap with the corresponding color filter CF of the color filter layer CFL and the corresponding lens of the lens LS array LA. Accordingly, at a center of the display area DA, the light emitted from the light emitting structure EMS may be efficiently output in a normal direction of a display surface. At an outskirt of the display area DA, the light emitted from the light emitting structure EMS may be efficiently output in a direction inclined by an angle (e.g., a predetermined angle) with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting the layers thereunder from a foreign substance, such as dust or moisture. For example, the overcoat layer OC may include at least one of an inorganic insulating layer or an organic insulating layer. For example, the overcoat layer OC may include an epoxy, but the present disclosure is not limited thereto. The overcoat layer OC may have a refractive index lower than that of the lens array LA.

The cover window CW may be disposed on the overcoat layer OC. The cover window CW may protect the layers thereunder. The cover window CW may have a refractive index higher than that of the overcoat layer OC. The cover window CW may include glass, but the present disclosure is not limited thereto. For example, the cover window CW may be an encapsulation glass to protect the components disposed thereunder. In other embodiments, the cover window CW may be omitted as needed or desired.

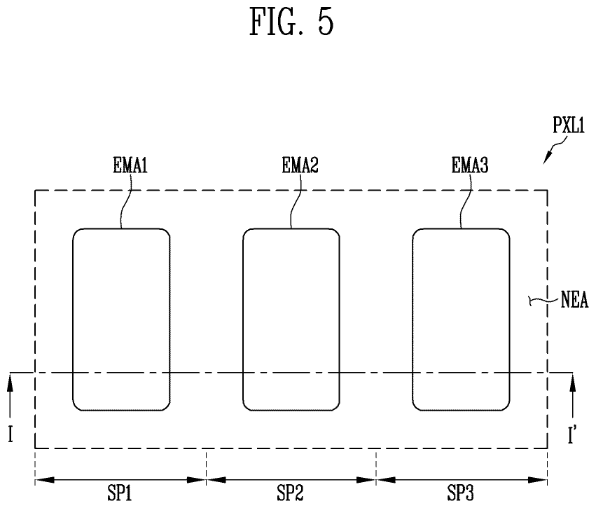

FIG. 5 is a plan view illustrating one pixel of FIG. 4, according to an embodiment. In FIG. 5, the first pixel PXL1 of the first and second pixels PXL1 and PXL2 described above with reference to FIG. 4 is schematically shown for convenience of illustration. The other remaining pixels may be configured the same or substantially the same as (or similarly to) that of the first pixel PXL1.

Referring to FIGS. 4 and 5, the first pixel PXL1 may include the first to third sub-pixels SP1 to SP3 arranged along the first direction DR1.

The first sub-pixel SP1 may include a first emission area EMA1, and a non-emission area NEA around the first emission area EMA1. The second sub-pixel SP2 may include a second emission area EMA2, and the non-emission area NEA around the second emission area EMA2. The third sub-pixel SP3 may include a third emission area EMA3, and the non-emission area NEA around the third emission area EMA3.

The first emission area EMA1 may be an area where light is emitted from a portion of the light emitting structure EMS (e.g., refer to FIG. 4) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3. As described above with reference to FIG. 4, each emission area may be understood as a corresponding opening OP of the pixel defining layer PDL corresponding to each of the first to third sub-pixels SP1 to SP3.

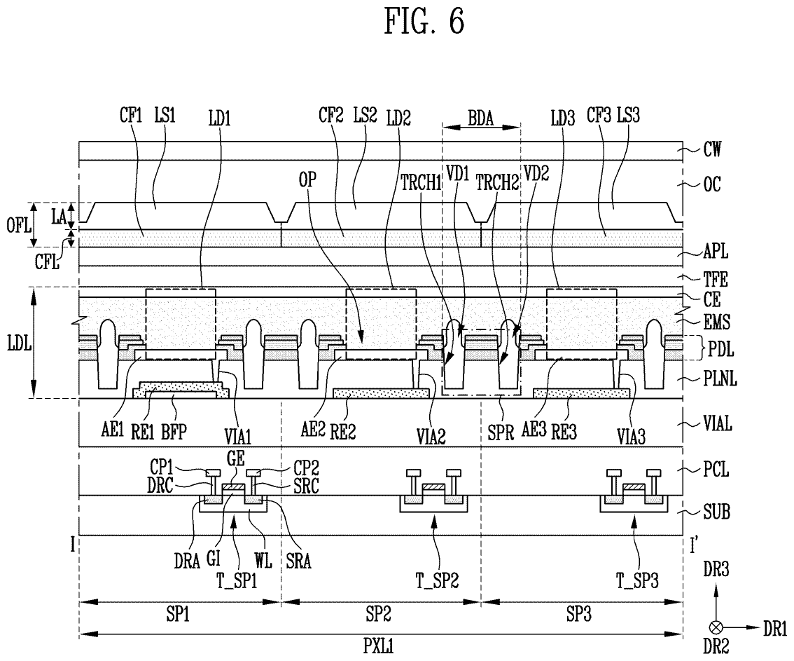

FIG. 6 is a cross-sectional view taken along the line I-I′ of FIG. 5.

Referring to FIG. 6, the pixel circuit layer PCL may be disposed on the substrate SUB.

The substrate SUB may include a silicon wafer substrate formed using a semiconductor process. For example, the substrate SUB may include silicon, germanium, and/or silicon-germanium.

The pixel circuit layer PCL is disposed on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (e.g., refer to FIG. 2) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 6, for convenience of illustration, one of the transistors of each sub-pixel is shown, and the other remaining circuit elements are not shown.

The transistor T_SP1 of the first sub-pixel SP1 may include a source area SRA, a drain area DRA, and a gate electrode GE.

The source area SRA and drain area DRA may be disposed in the substrate SUB. A well WL formed through an ion injection process may be disposed in the substrate SUB, and the source area SRA and the drain area DRA may be disposed to be spaced apart from each other in the well WL. An area between the source area SRA and the drain area DRA in the well WL may be defined as a channel area.

The gate electrode GE may overlap with the channel area between the source area SRA and the drain area DRA, and may be disposed in the pixel circuit layer PCL. The gate electrode GE may be spaced apart from the well WL or the channel area by an insulating material, such as a gate insulating layer GI. The gate electrode GE may include a conductive material.

A plurality of layers included in the pixel circuit layer PCL may include insulating layers, and conductive patterns disposed between the insulating layers. The conductive patterns may include first and second conductive patterns CP1 and CP2. The first conductive pattern CP1 may be electrically connected to the drain area DRA through a drain connection portion DRC passing through (e.g., penetrating) one or more insulating layers. The second conductive pattern CP2 may be electrically connected to the source area SRA through a source connection portion SRC passing through (e.g., penetrating) one or more insulating layers.

As the gate electrode GE and the first and second conductive patterns CP1 and CP2 are connected to different circuit elements and/or lines, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured the same or substantially the same as (or similarly to) that of the transistor T_SP1 of the first sub-pixel SP1.

As described above, the substrate SUB and the pixel circuit layer PCL may include the circuit elements of each of the first to third sub-pixels SP1 to SP3.

A via layer VIAL is disposed on the pixel circuit layer PCL. The via layer VIAL may cover the pixel circuit layer PCL, and may have an overall flat or substantially flat surface. The via layer VIAL may planarize or substantially planarize steps on the pixel circuit layer PCL. The via layer VIAL may include at least one of silicon oxide (SiOx), silicon nitride (SiNx), or silicon carbon nitride (SiCN), but the present disclosure is not limited thereto.

The light emitting element layer LDL is disposed on the via layer VIAL. The light emitting element layer LDL may include first to third reflective electrodes RE1 to RE3, a planarization layer PLNL, first to third anode electrodes AE1 to AE3, the pixel defining layer PDL, the light emitting structure EMS, and the cathode electrode CE.

On the via layer VIAL, the first to third reflective electrodes RE1 to RE3 are disposed in the first to third sub-pixels SP1 to SP3, respectively. Each of the first to third reflective electrodes RE1 to RE3 may contact the corresponding circuit element disposed in the pixel circuit layer PCL through a via passing through the via layer VIAL.

The first to third reflective electrodes RE1 to RE3 may function as a full mirror for reflecting the light emitted from the light emitting structure EMS toward the display surface (e.g., toward the cover window CW). The first to third reflective electrodes RE1 to RE3 may include metal materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or a suitable alloy of two or more materials selected therefrom.

In some embodiments, a connection electrode may be disposed under each of the first to third reflective electrodes RE1 to RE3. The connection electrode may improve an electrical connection characteristic between the reflective electrode and a corresponding circuit element of the pixel circuit layer PCL. The connection electrode may have a multilayered structure. The multilayered structure may include titanium (Ti), titanium nitride (TiN), tantalum nitride (TaN), or the like, but the present disclosure is not limited thereto. In some embodiments, a corresponding reflective electrode may be positioned between multiple layers of the connection electrode.

A buffer pattern BFP may be disposed under at least one of the reflective electrodes RE1 to RE3. The buffer pattern BFP may include an inorganic material, such as silicon carbon nitride, but the present disclosure is not limited thereto. By disposing the buffer pattern BFP, a height of the third direction DR3 of a corresponding reflective electrode may be adjusted. For example, the buffer pattern BFP may be disposed between the first reflective electrode RE1 and the via layer VIAL to adjust a height of the first reflective electrode RE1.

The first to third reflective electrodes RE1 to RE3 may function as full mirrors, and the cathode electrode CE may function as a half mirror. The light emitted from the light emitting layer of the light emitting structure EMS may be amplified by at least partially reciprocating between a corresponding reflective electrode and the cathode electrode CE, and the amplified light may be output through the cathode electrode CE. As described above, a distance between each reflective electrode and the cathode electrode CE may be understood as a resonance distance for the light emitted from the light emitting layer of the corresponding light emitting structure EMS.

The first sub-pixel SP1 may have a resonance distance shorter than that of the other sub-pixels by the buffer pattern BFP. The resonance distance adjusted as described above may allow light of a specific wavelength range (for example, a red color) to be effectively and efficiently amplified. Accordingly, the first sub-pixel SP1 may effectively and efficiently output light of a corresponding wavelength range.

In FIG. 6, the buffer pattern BFP is provided to the first sub-pixel SP1 and is not provided to the second and third sub-pixels SP2 and SP3, but the present disclosure is not limited thereto. The buffer pattern may also be provided in at least one of the second and/or third sub-pixels SP2 and/or SP3 to adjust the resonance distance of at least one of the second and/or third sub-pixels SP2 and/or SP3. For example, the first to third sub-pixels SP1 to SP3 may correspond to red, green, and blue, respectively, a distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

In order to planarize or substantially planarize the steps between the first to third reflective electrodes RE1 to RE3, the planarization layer PLNL may be disposed on the via layer VIAL and the first to third reflective electrodes RE1 to RE3. The planarization layer PLNL may generally cover the first to third reflective electrodes RE1 to RE3 and the via layer VIAL, and may have a flat or substantially flat surface. In some embodiments, the planarization layer PLNL may be omitted as needed or desired.

On the planarization layer PLNL, the first to third anode electrodes AE1 to AE3 overlapping with the first to third reflective electrodes RE1 to RE3, respectively, are disposed. The first to third anode electrodes AE1 to AE3 may have shapes similar to those of the first to third emission areas EMA1 to EMA3 described above with reference to FIG. 5 when viewed in the third direction DR3 (e.g., in a plan view). The first to third anode electrodes AE1 to AE3 are connected to the first to third reflective electrodes RE1 to RE3, respectively. The first anode electrode AE1 may be connected to the first reflective electrode RE1 through a first via VIA1 passing through (e.g., penetrating) the planarization layer PLNL. The second anode electrode AE2 may be connected to the second reflective electrode RE2 through a second via VIA2 passing through (e.g., penetrating) the planarization layer PLNL. The third anode electrode AE3 may be connected to the third reflective electrode RE3 through a third via VIA3 passing through (e.g., penetrating) the planarization layer PLNL.

In some embodiments, the first to third anode electrodes AE1 to AE3 may include at least one of suitable transparent conductive materials, such as indium tin oxide (ITO), indium zinc oxide (IZO), zinc oxide (ZnOx), indium gallium zinc oxide (IGZO), and/or indium tin zinc oxide (ITZO). However, the material of the first to third anode electrodes AE1 to AE3 is not limited thereto. For example, the first to third anode electrodes AE1 to AE3 may include titanium nitride.

In some embodiments, insulating layers for adjusting a height of one or more of the first to third anode electrodes AE1 to AE3 may be further provided. The insulating layers may be disposed between one or more of the first to third anode electrodes AE1 to AE3 and the corresponding reflective electrodes. In this case, the planarization layer PLNL and/or the buffer pattern BFP may be omitted. For example, the first to third sub-pixels SP1 to SP3 may correspond to red, green, and blue, respectively, a distance between the first anode electrode AE1 and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE. The pixel defining layer PDL is disposed on portions of the first to third anode electrodes AE1 to AE3 and the planarization layer PLNL. The pixel defining layer PDL may include the opening OP exposing a portion of each of the first to third anode electrodes AE1 to AE3. The opening OP of the pixel defining layer PDL may define the emission area of each of the first to third sub-pixels SP1 to SP3. The pixel defining layer PDL may be disposed in the non-emission area NEA described above with reference to FIG. 5, and may define the first to third emission areas EMA1 to EMA3.

In some embodiments, the pixel defining layer PDL may include a plurality of inorganic insulating layers. Each of the plurality of inorganic insulating layers may include at least one of silicon oxide (SiOx) or silicon nitride (SiNx). For example, the pixel defining layer PDL may include sequentially stacked first to third inorganic insulating layers, and each of the first to third inorganic insulating layers may include silicon nitride, silicon oxide, and/or silicon nitride. However, the present disclosure is not limited thereto. The first to third inorganic insulating layers may have a step shape of a cross-section in an area adjacent to the opening OP.

A separator SPR may be provided in a boundary area BDA between sub-pixels neighboring (e.g., adjacent to) each other. In other words, the separator SPR may be provided in each of the boundary areas between the sub-pixels SP described above with reference to FIG. 3.

The separator SPR may cause a formation of a discontinuity in the light emitting structure EMS in the boundary area BDA. For example, the light emitting structure EMS may be disconnected or bent in the boundary area BDA due to the separator SPR.

The separator SPR may be provided in or on the pixel defining layer PDL. The pixel defining layer PDL may include one or more trenches TRCH1 and TRCH2 as the separator SPR in the boundary area BDA. In some embodiments, as shown in FIG. 6, the one or more trenches TRCH1 and TRCH2 may pass through the pixel defining layer PDL, and may partially pass through the planarization layer PLNL. In other embodiments, the one or more trenches TRCH1 and TRCH2 may pass through the pixel defining layer PDL and the planarization layer PLNL, and may partially pass through the via layer VIAL. In other embodiments, the one or more trenches TRCH1 and TRCH2 may at least partially pass through the planarization layer PLNL and/or the via layer VIAL, and a portion of the pixel defining layer PDL may be disposed in the one or more trenches TRCH1 and TRCH2.

In FIG. 6, two trenches TRCH1 and TRCH2 are illustrated in the boundary area BDA. However, the present disclosure is not limited thereto. For example, the pixel defining layer PDL may include one trench in the boundary area BDA. As another example, the pixel defining layer PDL may include three or more trenches in the boundary area BDA.

Due to the first and second trenches TRCH1 and TRCH2 in the boundary area BDA, discontinuous portions, such as a first void VD1 and a second void VD2, may be formed in the light emitting structure EMS. A portion of a plurality of layers stacked in the light emitting structure EMS may be disconnected or bent by the first and second voids VD1 and VD2. For example, at least one charge generation layer included in the light emitting structure EMS may be disconnected in the first and second voids VD1 and VD2. As described above, portions of the light emitting structure EMS included in the first to third sub-pixels SP1 to SP3 may be at least partially separated due to the first and second trenches TRCH1 and TRCH2.

In FIG. 6, in the boundary area BDA, the first and second voids VD1 and VD2 are formed in the light emitting structure EMS, but the present disclosure is not limited thereto. For example, in the boundary area BDA, a valley of a concave shape may be formed in the light emitting structure EMS. According to the shapes of the first and second trenches TRCH1 and TRCH2, the discontinuous portions formed in the light emitting structure EMS may be variously modified.

In some embodiments, the light emitting structure EMS may be formed through a process of a vacuum deposition, inkjet printing, and/or the like. In this case, the same materials as that of the light emitting structure EMS may be positioned on bottom surfaces of the first and second trenches TRCH1 and TRCH2 adjacent to the via layer VIAL.

The separator SPR may be variously modified and provided, so that the light emitting structure EMS may have a discontinuous portion in the boundary area BDA. In some embodiments, inorganic insulating patterns additionally stacked on the pixel defining layer PDL may be provided in the boundary area BDA without the first and second trenches TRCH1 and TRCH2. From among the additionally stacked inorganic insulating patterns, a width of the uppermost inorganic insulating pattern may be greater than a width of an inorganic insulating pattern disposed immediately thereunder. For example, in the boundary area BDA, first to third inorganic insulating patterns may be sequentially stacked from the pixel defining layer PDL, and the uppermost third inorganic insulating pattern may have a width greater than that of the second inorganic insulating pattern. For example, the pixel defining layer PDL may have a “T” shape or an “I” shape of a cross-section in the boundary area BDA. According to the shape of the pixel defining layer PDL, a plurality of layers included in the light emitting structure EMS may be at least partially disconnected or bent in the boundary area BDA.

The light emitting structure EMS may be disposed on the anode electrodes AE1 to AE3 exposed by the opening OP of the pixel defining layer PDL. The light emitting structure EMS may fill the opening OP of the pixel defining layer PDL, and may be disposed entirely across the first to third sub-pixels SP1 to SP3. As described above, the light emitting structure EMS may be at least partially disconnected or bent in the boundary area BDA by the separator SPR. Accordingly, when the display panel DP is operated, a current flowing out from each of the first to third sub-pixels SP1 to SP3 to a sub-pixel adjacent thereto through the layers included in the light emitting structure EMS may be decreased. Therefore, the first to third light emitting elements LD1 to LD3 may operate with a relatively high reliability.

The cathode electrode CE may be disposed on the light emitting structure EMS. The cathode electrode CE may be commonly provided to the first to third sub-pixels SP1 to SP3. The cathode electrode CE may function as a half mirror that partially transmits and partially reflects the light emitted from the light emitting structure EMS.

The first anode electrode AE1, a portion of the light emitting structure EMS overlapping with the first anode electrode AE1, and a portion of the cathode electrode CE overlapping with the first anode electrode AE1 may configure the first light emitting element LD1. The second anode electrode AE2, a portion of the light emitting structure EMS overlapping with the second anode electrode AE2, and a portion of the cathode electrode CE overlapping with the second anode electrode AE2 may configure the second light emitting element LD2. The third anode electrode AE3, a portion of the light emitting structure EMS overlapping with the third anode electrode AE3, and a portion of the cathode electrode CE overlapping with the third anode electrode AE3 may configure the third light emitting element LD3.

The encapsulation layer TFE is disposed on the cathode electrode CE. The encapsulation layer TFE may prevent or substantially prevent oxygen, moisture, and/or the like from permeating to the light emitting element layer LDL.

The optical functional layer OFL is disposed on the encapsulation layer TFE. In some embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting the lower layers including the encapsulation layer TFE.

The optical functional layer OFL may include the color filter layer CFL and the lens array LA. The color filter layer CFL may include first to third color filters CF1 to CF3 corresponding to the first to third sub-pixels SP1 to SP3, respectively. The first to third color filters CF1 to CF3 may pass light of different wavelength ranges from each other. For example, the first to third color filters CF1 to CF3 may pass light of red, green, and blue colors, respectively.

In some embodiments, the first to third color filters CF1 to CF3 may partially overlap with each other in the boundary area BDA. In other embodiments, the first to third color filters CF1 to CF3 may be spaced apart from each other, and a black matrix may be provided between the first to third color filters CF1 to CF3.

The lens array LA is disposed on the color filter layer CFL. The lens array LA may include first to third lenses LS1 to LS3 corresponding to the first to third sub-pixels SP1 to SP3, respectively. Each of the first to third lenses LS1 to LS3 may improve a light output efficiency by outputting light emitted from the first to third light emitting elements LD1 to LD3 to an intended path.

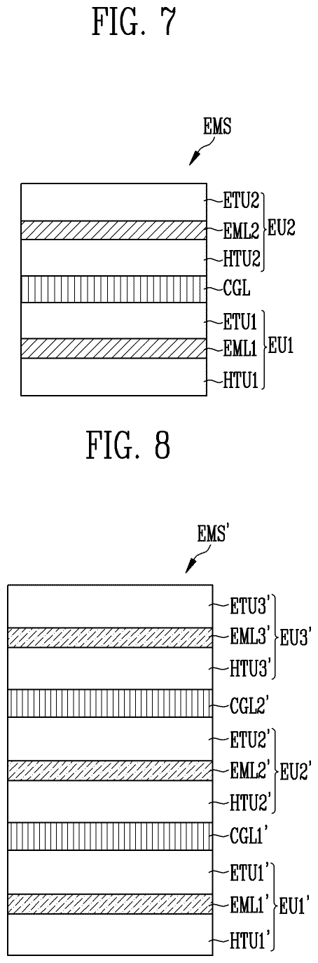

FIG. 7 is a cross-sectional view of a light emitting structure included in one light emitting element of FIG. 6, according to an embodiment.

Referring to FIG. 7, the light emitting structure EMS may have a tandem structure in which first and second light emitting units or stacks EU1 and EU2 are stacked. The light emitting structure EMS may be configured the same or substantially the same in each of the first to third light emitting elements LD1 to LD3 described above with reference to FIG. 6.

Each of the first and second light emitting units EU1 and EU2 may include at least one light emitting layer that generates light according to an applied current. The first light emitting unit EU1 may include a first light emitting layer EML1, a first electron transport unit or layer ETU1, and a first hole transport unit or layer HTU1. The first light emitting layer EML1 may be disposed between the first electron transport unit ETU1 and the first hole transport unit HTU1. The second light emitting unit EU2 may include a second light emitting layer EML2, a second electron transport unit or layer ETU2, and a second hole transport unit or layer HTU2. The second light emitting layer EML2 may be disposed between the second electron transport unit ETU2 and the second hole transport unit HTU2.

Each of the first and second hole transport units HTU1 and HTU2 may include at least one of a hole injection layer and/or a hole transport layer, and may further include a hole buffer layer, an electron blocking layer, and the like, if necessary or desired. The first and second hole transport units HTU1 and HTU2 may have configurations that are the same or substantially the same as each other, or may be different from each other.

Each of the first and second electron transport units ETU1 and ETU2 may include at least one of an electron injection layer and/or an electron transport layer, and may further include an electron buffer layer, a hole blocking layer, and the like, if necessary or desired. The first and second electron transport units ETU1 and ETU2 may have configurations that are the same or substantially the same as each other, or may be different from each other.

A connection layer, which may be provided in the form of a charge generation layer CGL, may be disposed between the first light emitting unit EU1 and the second light emitting unit EU2 to connect the first light emitting unit EU1 and the second light emitting unit EU2 to each other. In some embodiments, the charge generation layer CGL may have a stacked structure of a p dopant layer and an n dopant layer. For example, the p dopant layer may include a p-type dopant, such as HAT-CN, TCNQ, and/or NDP-9, and the n dopant layer may include an alkali metal, an alkaline earth metal, a lanthanide metal, or a suitable combination thereof. However, the present disclosure is not limited thereto.

In some embodiments, the first light emitting layer EML1 and the second light emitting layer EML2 may generate light of different colors from each other. Light emitted from each of the first light emitting layer EML1 and the second light emitting layer EML2 may be mixed together and viewed as white light. For example, the first light emitting layer EML1 may generate blue light, and the second light emitting layer EML2 may generate yellow light. In some embodiments, the second light emitting layer EML2 may include a structure in which a first sub light emitting layer to generate red light and a second sub light emitting layer to generate green light are stacked. The red light and the green light may be mixed together, and thus, the yellow light may be provided. In this case, an intermediate layer to perform a function of transporting holes and/or blocking the transport of electrons may be further disposed between the first and second sub light emitting layers.

In other embodiments, the first light emitting layer EML1 and the second light emitting layer EML2 may generate light of the same color as each other.

The light emitting structure EMS may be formed through a suitable method, such as vacuum deposition and/or inkjet printing, but the present disclosure is not limited thereto.

FIG. 8 is a cross-sectional view of a light emitting structure included in one light emitting element of FIG. 6, according to an embodiment.

Referring to FIG. 8, the light emitting structure EMS' may have a tandem structure in which first to third light emitting units or stacks EU1′ to EU3′ are stacked. The light emitting structure EMS' may be configured the same or substantially the same in each of the first to third light emitting elements LD1 to LD3 described above with reference to FIG. 6.

Each of the first to third light emitting units EU1′ to EU3′ may include a light emitting layer that generates light according to an applied current. The first light emitting unit EU1′ may include a first light emitting layer EML1′, a first electron transport unit or layer ETU1′, and a first hole transport unit or layer HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit or layer ETU2′, and a second hole transport unit or layer HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit or layer ETU3′, and a third hole transport unit or layer HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and/or a hole transport layer, and may further include a hole buffer layer, an electron blocking layer, and the like, if necessary or desired. The first to third hole transport units HTU1′ to HTU3′ may have configurations that are the same or substantially the same as each other, or may be different from each other.

Each of the first to third electron transport units ETU1′ to ETU3′ may include at least one of an electron injection layer and/or an electron transport layer, and may further include an electron buffer layer, a hole blocking layer, and the like, if necessary or desired. The first to third electron transport units ETU1′ to ETU3′ may have configurations that are the same or substantially the same as each other, or may be different from each other.

A first charge generation layer CGL1′ is disposed between the first light emitting unit EU1′ and the second light emitting unit EU2′. A second charge generation layer CGL2′ is disposed between the second light emitting unit EU2′ and the third light emitting unit EU3′.

In some embodiments, the first to third light emitting layers EML1′ to EML3′ may generate light of different colors from each other. The light emitted from each of the first to third light emitting layers EML1′ to EML3′ may be mixed together, and may be viewed as white light. For example, the first emitting layer EML1′ may generate light of a blue color, the second emitting layer EML2′ may generate light of a green color, and the third emitting layer EML3′ may generate light of a red color.

In other embodiments, two or more of the first to third light emitting layers EML1′ to EML3′ may generate light of the same color as each other.

Differently from that described above with reference to FIGS. 7 and 8, the light emitting structure EMS described above with reference to FIG. 6 may include one light emitting unit or stack in each of the first to third light emitting elements LD1 to LD3. In this case, the light emitting unit included in each of the first to third light emitting elements LD1 to LD3 may emit light of different colors from each other. For example, the light emitting unit of the first light emitting element LD1 may emit light of the red color, the light emitting unit of the second light emitting element LD2 may emit light of the green light, and the light emitting unit of the third light emitting element LD3 may emit light of the blue color. In this case, differently from that described above with reference to FIG. 6, the light emitting units of the first to third sub-pixels SP1 to SP3 may be spaced apart (e.g., may be separated) from each other, and each of them may be disposed in the corresponding opening OP of the pixel defining layer PDL. In this case, at least a portion of the color filters CF1 to CF3 may be omitted as needed or desired.

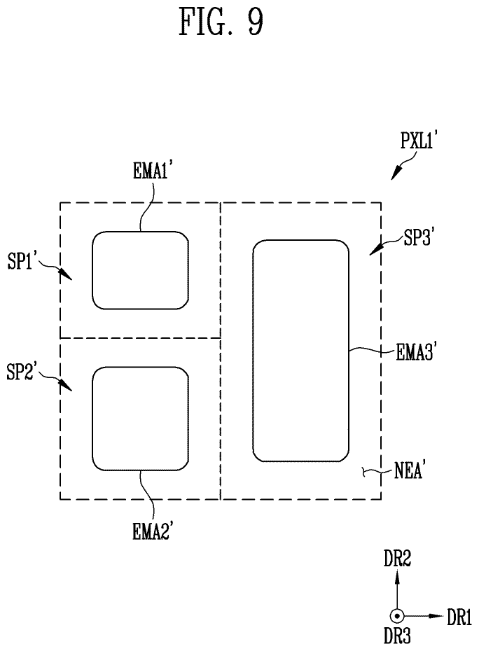

FIG. 9 is a plan view illustrating one pixel of FIG. 4, according to an embodiment.

Referring to FIG. 9, a first pixel PXL1′ may include first to third sub-pixels SP1′ to SP3′.

The first sub-pixel SP1′ may include a first emission area EMA1′, and a non-emission area NEA′ around the first emission area EMA1′. The second sub-pixel SP2′ may include a second emission area EMA2′, and the non-emission area NEA′ around the second emission area EMA2′. The third sub-pixel SP3′ may include a third emission area EMA3′, and the non-emission area NEA′ around the third emission area EMA3′.

The first sub-pixel SP1′ and the second sub-pixel SP2′ may be arranged along the second direction DR2. The third sub-pixel SP3′ may be arranged along the first direction DR1 with respect to each of the first and second sub-pixels SP1′ and SP2′.

The second sub-pixel SP2′ may have an area greater than that of the first sub-pixel SP1′, and the third sub-pixel SP3′ may have an area greater than that of the second sub-pixel SP2′. Accordingly, the second emission area EMA2′ may have an area greater than that of the first emission area EMA1′, and the third emission area EMA3′ may have an area greater than that of the second emission area EMA2′. However, the present disclosure is not limited thereto. For example, the first and second sub-pixels SP1′ and SP2′ may have the same or substantially the same area as each other, and the third sub-pixel SP3′ may have an area greater than that of each of the first and second sub-pixels SP1′ and SP2′. As described above, the areas of the first to third sub-pixels SP1′ to SP3′ may be variously modified as needed or desired.

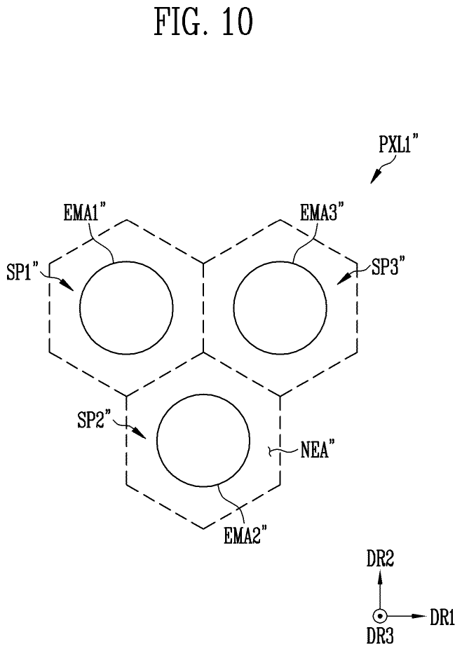

FIG. 10 is a plan view illustrating one pixel of FIG. 4, according to an embodiment.

Referring to FIG. 10, a first sub-pixel SP1″ may include a first emission area EMA1″, and a non-emission area NEA″ around the first emission area EMA1″. A second sub-pixel SP2″ may include a second emission area EMA2″, and the non-emission area NEA″ around the second emission area EMA2″. A third sub-pixel SP3″ may include a third emission area EMA3″, and the non-emission area NEA″ around the third emission area EMA3″.

The first to third sub-pixels SP1″ to SP3″ may have polygonal shapes when viewed in the third direction DR3 (e.g., in a plan view). For example, shapes of the first to third sub-pixels SP1″ to SP3″ may be hexagonal shapes as shown in FIG. 10.

The first to third emission areas EMA1″ to EMA3″ may have circular shapes when viewed in the third direction DR3 (e.g., in a plan view). However, the present disclosure is not limited thereto. For example, each of the first to third emission areas EMA1″ to EMA3″ may have a polygonal shape.

The first and third sub-pixels SP1″ and SP3″ may be arranged along the first direction DR1. The second sub-pixel SP2″ may be disposed in a direction inclined by an acute angle based on the second direction DR2 (e.g., a diagonal direction) with respect to the first sub-pixel SP1″.

An arrangement of the sub-pixels shown in FIGS. 5, 9, and 10 is provided as examples, and the present disclosure is not limited thereto. Each pixel may include two or more sub-pixels SP, the sub-pixels SP may be arranged in various suitable methods, the sub-pixels may have various suitable shapes, and the emission areas EMA1, EMA2, and EMA3 thereof may also have various suitable shapes.

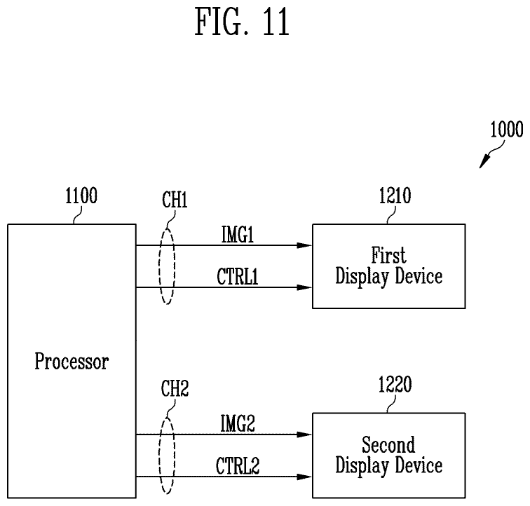

FIG. 11 is a block diagram illustrating a display system, according to an embodiment.

Referring to FIG. 11, the display system 1000 may include a processor 1100, and one or more display devices 1210 and 1220.

The processor 1100 may perform various suitable tasks and calculations. In some embodiments, the processor 1100 may include an application processor, a graphic processor, a microprocessor, a central processing unit (CPU), and/or the like. The processor 1100 may be connected to other components of the display system 1000 through a bus system, and may control the other components.

In FIG. 11, the display system 1000 includes the first and second display devices 1210 and 1220. The processor 1100 may be connected to the first display device 1210 through a first channel CH1, and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured the same or substantially the same as (or similarly to) the display device 100 described above with reference to FIG. 1. In this case, the first image data IMG1 and the first control signal CTRL1 may be provided as the input image data IMG and the control signal CTRL described above with reference to FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured the same or substantially the same as (or similarly to) the display device 100 described above with reference to FIG. 1. In this case, the second image data IMG2 and the second control signal CTRL2 may be provided as the input image data IMG and the control signal CTRL described above with reference to FIG. 1, respectively.

The display system 1000 may include a computing system for providing an image display function, such as a portable computer, a mobile phone, a smart phone, a tablet personal computer (PC), a smart watch, a watch phone, a portable multimedia player (PMP), a navigation device, and an ultra mobile personal computer (UMPC). In addition, the display system 1000 may include at least one of a head mounted display (HMD) device, a virtual reality (VR) device, a mixed reality (MR) device, or an augmented reality (AR) device.

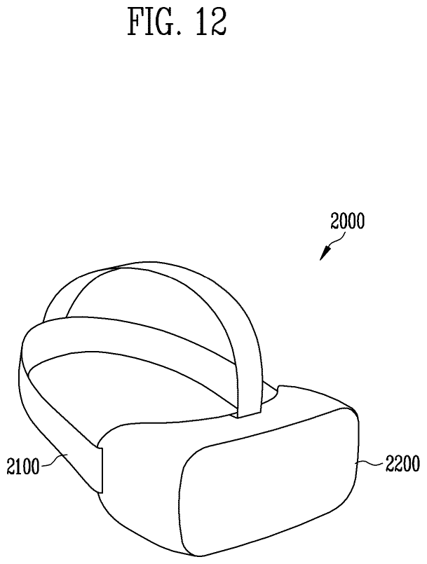

FIG. 12 is a perspective view illustrating an application example of the display system of FIG. 11.

Referring to FIG. 12, the display system 1000 described above with reference to FIG. 11 may be applied to a head mounted display device 2000. The head mounted display device 2000 may be a wearable electronic device that may be worn on a user's head.

The head mounted display device 2000 may include a head mount band 2100 and a display device receiving case 2200. The head mount band 2100 may be connected to the display device receiving case 2200. The head mount band 2100 may include a horizontal band and/or a vertical band for fixing the head mounted display device 2000 to the user's head. The horizontal band may surround (e.g., around a periphery of) a side portion of the user's head, and the vertical band may surround (e.g., around a periphery of) an upper portion of the user's head. However, the present disclosure is not limited thereto. For example, the head mount band 2100 may be implemented in a glasses frame form, a helmet form, or the like.

The display device receiving case 2200 may receive the first and second display devices 1210 and 1220 described above with reference to FIG. 11. The display device receiving case 2200 may further receive the processor 1100 described above with reference to FIG. 11.

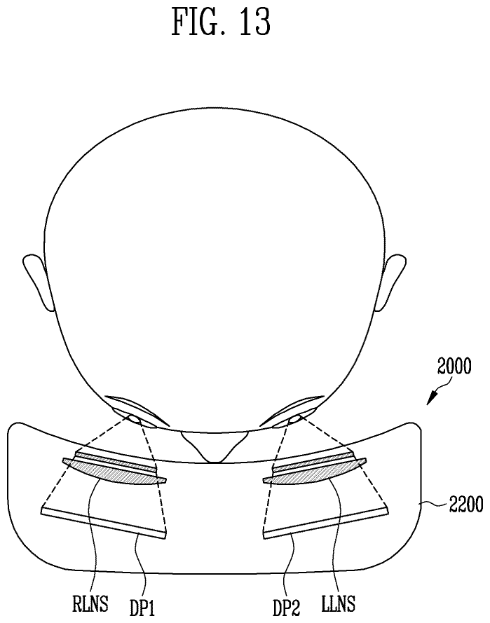

FIG. 13 is a diagram illustrating the head mounted display device of FIG. 12 worn by a user.

Referring to FIG. 13, in the head mounted display device 2000, a first display panel DP1 of the first display device 1210 and a second display panel DP2 of the second display device 1220 are disposed. The head mounted display device 2000 may further include one or more lenses LLNS and RLNS.

Within the display device receiving case 2200, the right eye lens RLNS may be disposed between the first display panel DP1 and the user's right eye. Within the display device receiving case 2200, the left eye lens LLNS may be disposed between the second display panel DP2 and the user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In some embodiments, each of the right eye lens RLNS and the left eye lens LLNS may include an optical lens having a pancake-shaped cross-section. In some embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas and may be displayed to the user.

FIG. 14 is a diagram illustrating a distance between the display panel shown in FIG. 13 and a user's eye. The display panel DP shown in FIG. 14 may be one of the first display panel DP1 or the second display panel DP2 shown in FIG. 13. A lens LNS shown in FIG. 14 may be one of the right eye lens RLNS or the left eye lens LLNS shown in FIG. 13. As described above with reference to FIG. 4, the display panel DP of FIG. 14 is shown to include the substrate SUB, the pixel circuit layer PCL, the light emitting element layer LDL, the encapsulation layer TFE, the optical functional layer OFL, the overcoat layer OC, and the cover window CW.

Referring to FIG. 14, light from the display panel DP passes through the lens LNS and is directed to the user's left or right eye. As such, the lens LNS may have a focal length (e.g., a certain or predetermined focal length) FL. In the head mounted display device 2000, the display panel DP and the lens LNS may be disposed to be spaced apart from each other by a distance D1. In this case, a distance from an upper portion of the display panel DP to the user's eye is “D1+FL”.

As shown in FIG. 14, the lens LNS is disposed at a suitable distance (e.g., a certain or predetermined distance) from the display panel DP, so that an image output from the display panel DP may be viewed to the user's eyes. In addition, an appropriate distance from the lens LNS to the user's eyes may be desired, so that the image output from the display panel DP may be viewed to the user's eyes. As such, a size for the display device receiving case 2200 may be increased. As a result, user convenience may decrease due to an increase in the entire volume and weight of the head mounted display device 2000.

According to some embodiments of the present disclosure, the display panel includes a light path conversion unit or layer that converts a path of light generated from each sub-pixel. Accordingly, a distance between the display panel and the user's eyes may be shortened, and a size and a weight of the head mounted display device may be reduced.

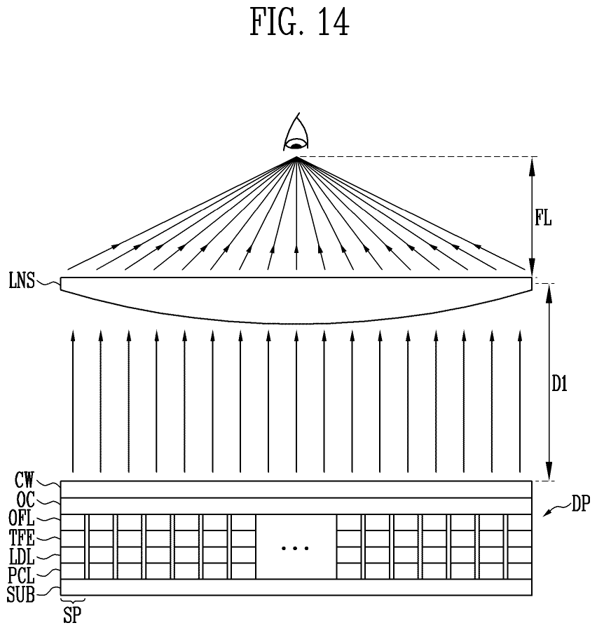

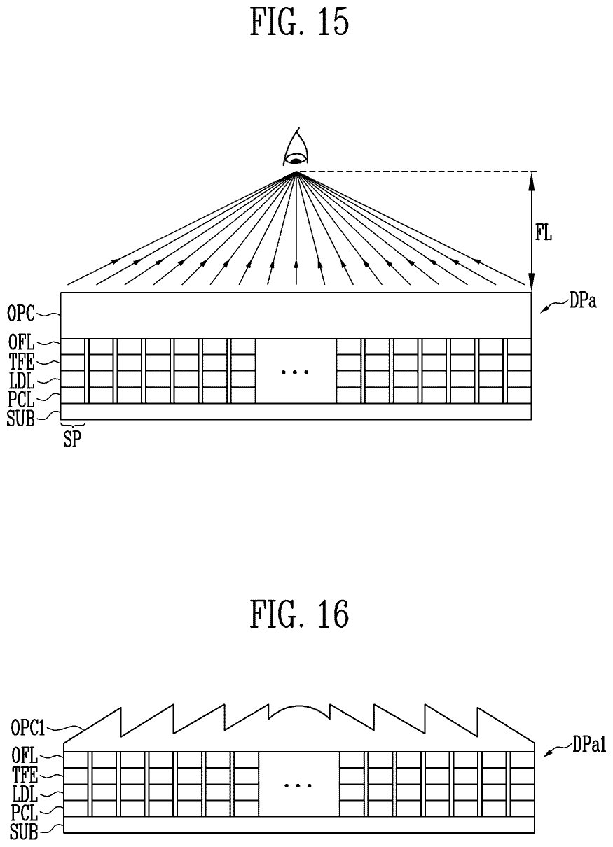

FIG. 15 is a cross-sectional view illustrating a display panel of a display device, according to an embodiment.

Referring to FIG. 15, the display panel DPa of the display device according to another embodiment of the present disclosure may include a light path conversion unit or layer OPC. As illustrated in FIG. 15, in some embodiments, the light path conversion unit OPC may be formed at the uppermost portion of the display panel DPa. As used herein, the pixel circuit layer PCL, the light emitting element layer LDL, the encapsulation layer TFE, and the optical functional layer OFL formed sequentially on the substrate SUB may be referred to as a “pixel structure layer”. The pixel circuit layer PCL, the light emitting element layer LDL, the encapsulation layer TFE, and the optical functional layer OFL included in the pixel structure layer configures a plurality of sub-pixels. In FIG. 15, the light path conversion unit OPC may be formed on the pixel structure layer.

For example, as shown in FIG. 15, the light path conversion unit OPC may be formed on the optical functional layer OFL of the display panel DPa. Referring to FIGS. 14 and 15 together, the display panel DP described above with reference to FIG. 14 includes the overcoat layer OC and the cover window CW on the optical functional layer OFL. However, in the display panel DPa of FIG. 15, the light path conversion unit OPC may be formed on the optical functional layer OFL, and the overcoat layer OC and the cover window CW may not be included in the display panel DPa. However, the present disclosure is not limited thereto, and the display panel DPa may include at least one of the overcoat layer OC or the cover window CW on or under the light path conversion unit OPC.

The light path conversion unit OPC converts a path of light generated from each sub-pixel SP of the display panel DPa. In some embodiments, the light path conversion unit OPC may converge the light generated from each sub-pixel SP of the display panel DPa to the user's eyes. In other words, the light path conversion unit OPC may include a lens having a focal length FL. Because the light path conversion unit OPC converges the light from the display panel DPa, the head mounted display device 2000 may include only the display panel DPa, and may not include the lens LNS described above with reference to FIG. 14. As another example, the head mounted display device may include a lens having a focal length shorter than that of the lens LNS described above with reference to FIG. 14 together with the display panel DPa.

Accordingly, the distance between the display panel DPa of the head mounted display device and the user's eyes may be shortened, and the size and the weight of the head mounted display device may be reduced.

In FIG. 15, the light path conversion unit OPC is shown to converge the light generated from the display panel DPa, but the present disclosure is not limited thereto. For example, the light path conversion unit OPC may emit the light generated from the display panel DPa. In another example, instead of converging or emitting the light generated from the display panel DPa, the light path conversion unit OPC may only change a progress direction of the light. According to an embodiment, the light path conversion unit OPC may converge or emit the light generated from the display panel DPa, and may change the progress direction of the light.

As used herein, the light path conversion unit may be distinguished from the lens array LA described above with reference to FIG. 5, or from the first to third lenses LS1 to LS3 included in the lens array LA. Each of the first to third lenses LS1 to LS3 included in the lens array LA outputs light emitted from the light emitting element of a corresponding sub-pixel to an intended path. In comparison, the light path conversion unit OPC changes the path of the light emitted from the light emitting element included in the entire pixel structure layer in the display panel DPa.

FIG. 16 is a diagram illustrating the light path conversion unit of FIG. 15, according to an embodiment.

Referring to FIG. 16, a display panel DPa1 in which a light path conversion unit or layer OPC1 is implemented with a Fresnel lens is shown. The Fresnel lenses, unlike the curved surfaces of an optical lens, may include a plurality of grooves having a concentric shape. Each groove of the Fresnel lens may act like an individual refractive surface, and may refract light. When the Fresnel lens is used as the light path conversion unit OPC1, a thickness and a weight of the light path conversion unit may be reduced. In an embodiment, the Fresnel lens may be formed on an upper layer of the display panel DPa1 to have a sheet shape.

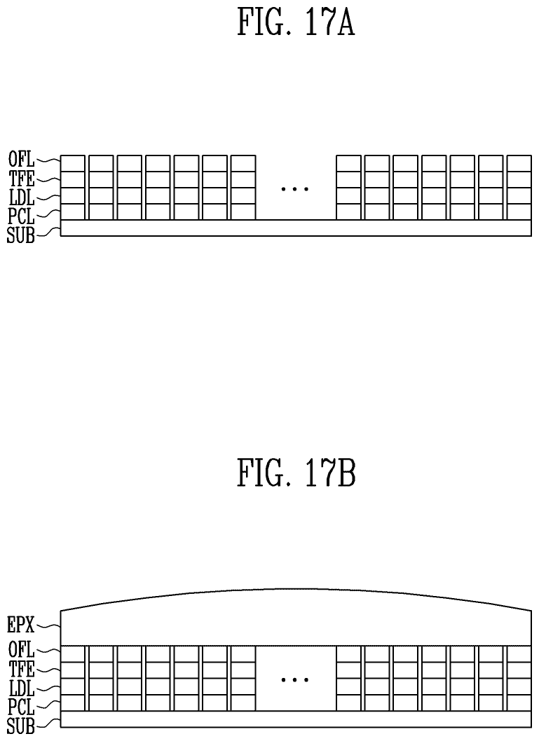

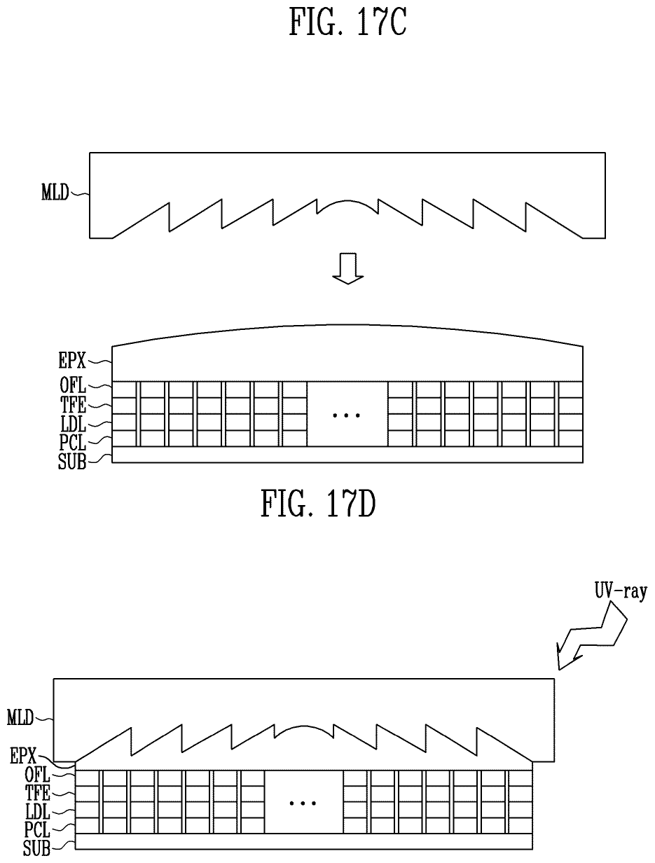

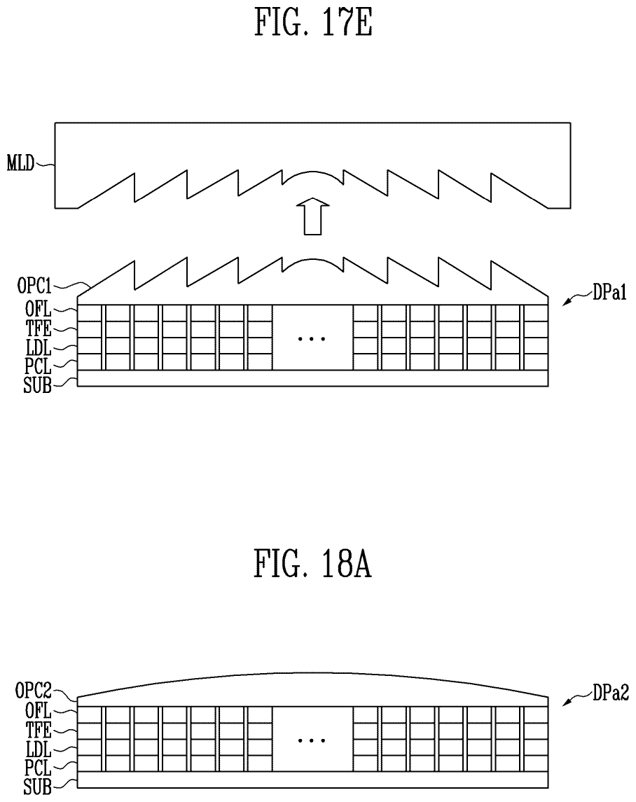

FIGS. 17A through 17E are diagrams illustrating a method of manufacturing the display panel shown in FIG. 16.

Referring to FIG. 17A, the pixel circuit layer PCL, the light emitting element layer LDL, the encapsulation layer TFE, and the optical functional layer OFL are sequentially formed on the substrate SUB. In other words, the pixel structure layer is formed on the substrate SUB. Referring to FIG. 17B, thereafter, a resin layer EPX is formed on the optical functional layer OFL of the pixel structure layer. The resin layer EPX may include an epoxy resin. However, the material of the resin layer is not limited thereto.

Referring to FIG. 17C, a mold MLD having an intaglio pattern of the Fresnel lens may be pressed on the resin layer EPX. Accordingly, an upper surface of the resin layer EPX may be transformed into a shape of the Fresnel lens. Referring to FIG. 17D, the resin layer EPX may be cured by irradiating ultraviolet rays in a state in which the mold MLD is pressed on the resin layer EPX. Thereafter, the mold MLD is separated from the resin layer as shown in FIG. 17E. The separated resin layer may become the light path conversion unit OPC1 implemented with the Fresnel lens having a pattern corresponding to the pattern of the mold MLD. As shown in FIGS. 17A to 17E, when the Fresnel lens is formed by coating the resin layer EPX on the optical function layer OFL, a thickness of the light path conversion unit OPC1 may be reduced, and as a result, a thickness of the display panel DPa1 may also be reduced.

The Fresnel lens formed of an epoxy resin on the pixel structure layer may partially serve as the overcoat layer OC. In other words, by the cured resin layer EPX, the lower layers thereof may be protected from a foreign substance, such as dust or moisture.

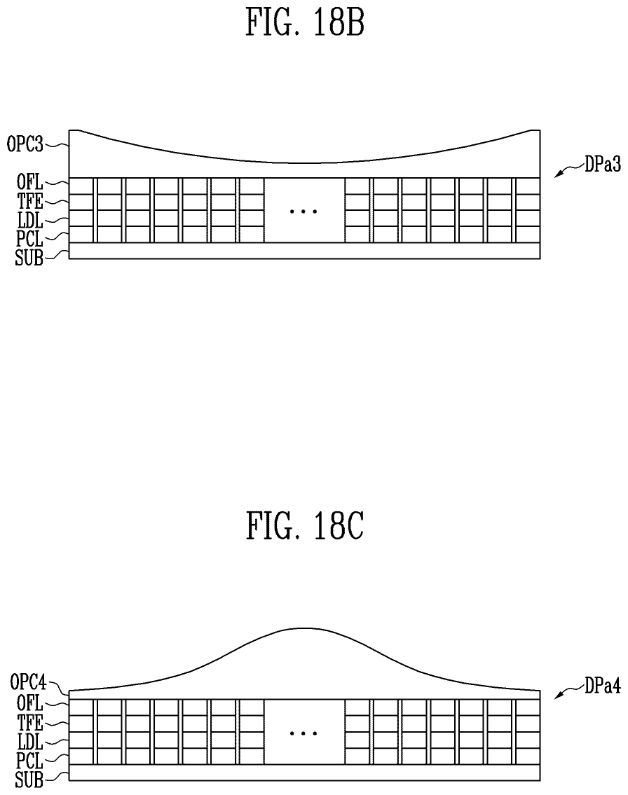

FIGS. 18A through 18C are diagrams illustrating the light path conversion unit of FIG. 15, according to one or more embodiments.

Referring to FIG. 18A, a display panel DPa2 in which a light path conversion unit or layer OPC2 is implemented with a convex lens is shown. Referring to FIG. 18B, a display panel DPa3 in which a light path conversion unit or layer OPC3 is implemented with a concave lens is shown. Referring to FIG. 18C, a display panel DPa4 in which a light path conversion unit or layer OPC4 is implemented with an aspherical lens is shown.

Although the Fresnel lens described above with reference to FIG. 16 may be desirable in terms of a thickness and a weight, a spherical or aspherical lens may be desired in terms of quality of an image perceived by the user's eyes. Therefore, in some embodiments, as shown in FIGS. 18A to 18C, the light path conversion units OPC2, OPC3, and OPC4 may be implemented with a convex lens, a concave lens, or an aspherical lens.

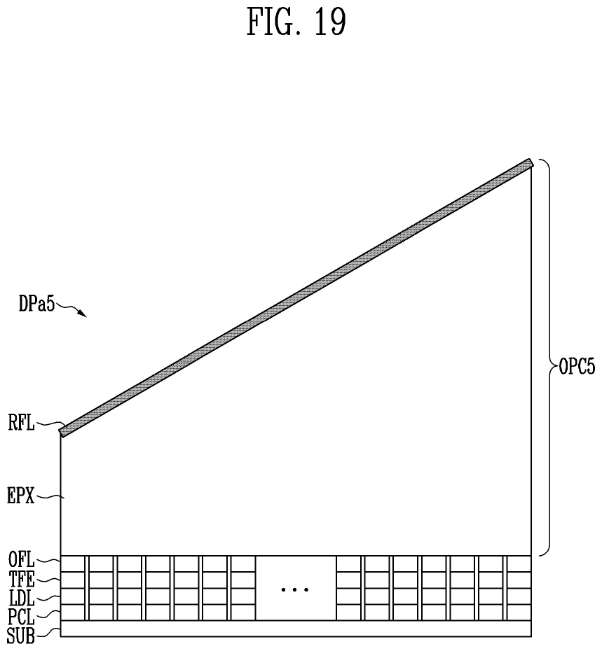

FIG. 19 is a diagram illustrating the light path conversion unit of FIG. 15, according to an embodiment.

Referring to FIG. 19, a light path conversion unit or layer OPC5 included in a display panel DPa5 may include a resin layer EPX and a reflective layer RFL. The reflective layer RFL may change a movement direction of light by reflecting the light generated from each sub-pixel of the display panel DPa5. In an embodiment, the reflective layer RFL may be formed to have an angle of 45 degrees with respect to a progress direction of light emitted from the sub-pixels. In this case, incident light entering the reflective layer RFL and the reflected light reflected from the reflective layer RFL may form an angle of 90 degrees with each other. When the light path conversion unit OPC5 included in the display panel DPa5 includes the reflective layer RFL, a disposition position of the display panel DPa5 may be designed more freely in the head mounted display device. The reflective layer RFL may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), or a suitable alloy of two or more materials selected from among them, but the present disclosure is not limited thereto.

In FIG. 19, the light path conversion unit OPC5 is shown as having a planar shape of the reflective layer RFL, but the present disclosure is not limited thereto. For example, the light path conversion unit may include a curved shape of the reflective layer. In this case, the light path conversion unit may change the progress direction of the light generated from the sub-pixels, and converge or emit the light generated from the sub-pixels. For example, when the reflective layer has a shape of a convex mirror, the light path conversion unit may change the progress direction of the light generated from the sub-pixels, and emit the light. In addition, when the reflective layer has a shape of a concave mirror, the light path conversion unit may change the progress direction of the light generated from the sub-pixels, and converge the light. In addition, the reflective layer may have a shape of an aspherical mirror.

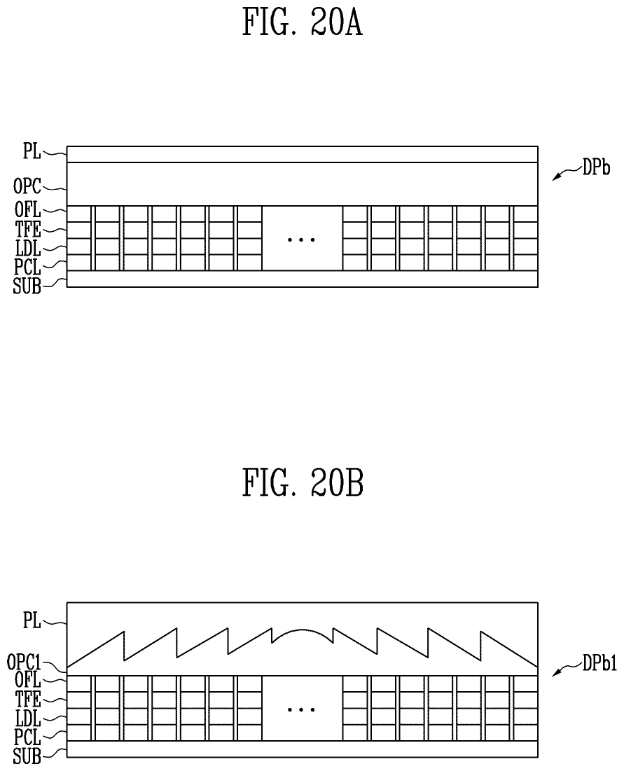

FIGS. 20A and 20B are cross-sectional views illustrating a display panel of a display device, according to one or more embodiments.

Referring to FIG. 20A, a display panel DPb may further include a protective layer PL formed on the light path conversion unit OPC. The protective layer PL may include various materials suitable for protecting the light path conversion unit OPC, so that the light path conversion unit OPC maintains or substantially maintains an optical property. For example, the protective layer PL may include a polymer, but the present disclosure is not limited thereto.

Referring to FIG. 20B, when a display panel DPb1 includes a light path conversion unit or layer OPC1 that is implemented with a Fresnel lens, the protective layer PL may be formed on the light path conversion unit OPC1. After the Fresnel lens is formed and cured, the protective layer PL may be formed on the Fresnel lens to protect a surface shape of the Fresnel lens.

In some embodiments, a cover window may be further formed on the protective layer PL.

In addition, in FIG. 20B, an embodiment in which the light path conversion unit OPC1 is implemented with the Fresnel lens is shown, but the present disclosure is not limited thereto. For example, the light path conversion unit OPC shown in FIG. 20A may include at least one of a convex lens, a concave lens, an aspherical lens, a plane mirror, a convex mirror, a concave mirror, or an aspherical mirror.

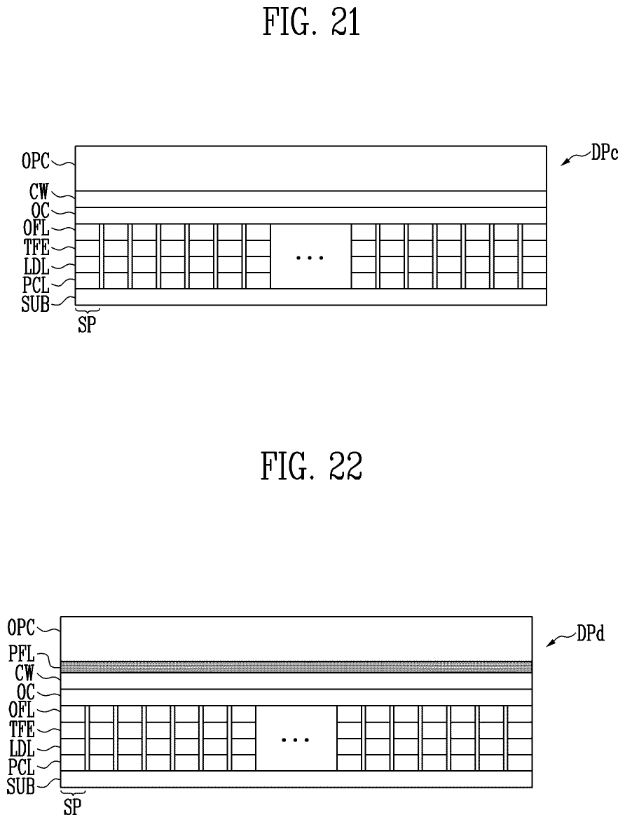

FIG. 21 is a cross-sectional view illustrating a display panel of a display device, according to an embodiment.

Referring to FIG. 21, an embodiment of a display panel DPc in which the light path conversion unit OPC is disposed on the cover window CW is shown. In the embodiments shown in FIGS. 15 to 20B, the light path conversion unit is formed on the optical functional layer OFL included in the pixel structure layer, and the overcoat layer OC and the cover window CW are not included in the display panel. However, according to the embodiment shown in FIG. 21, the overcoat layer OC and the cover window CW are formed on the optical function layer OFL of the pixel structure layer, and the light path conversion unit OPC is formed thereon.

FIG. 22 is a cross-sectional view illustrating a display panel of a display device, according to an embodiment.

Referring to FIG. 22, a display panel DPd in which a polarizing film layer PFL is included between the light path conversion unit OPC and the cover window CW is shown. By disposing the polarizing film layer PFL under the light path conversion unit OPC, characteristics of light transmitted to the light path conversion unit OPC may be improved.

In FIG. 22, an embodiment in which the cover window CW is formed on the overcoat layer OC, the polarizing film layer PFL is formed on the cover window CW, and the light path conversion unit OPC is formed is shown, but the disclosure is not limited thereto.

According to an embodiment, the cover window CW described above with reference to FIG. 22 may be omitted. In this case, the polarizing film layer PFL may be formed on the overcoat layer OC, and the light path conversion unit OPC may be formed on the polarizing film layer PFL.

According to an embodiment, the polarizing film layer PFL may be disposed under the cover window CW. In this case, the polarizing film layer PFL may be formed on the overcoat layer OC, the cover window CW may be formed on the polarizing film layer PFL, and the light path conversion unit OPC may be formed.

According to an embodiment, the cover window CW may be disposed on the light path conversion unit OPC. In this case, the polarizing film layer PFL may be formed on the overcoat layer OC, the light path conversion unit OPC may be formed on the polarizing film layer PFL, and the cover window CW may be formed on the light path conversion unit OPC.

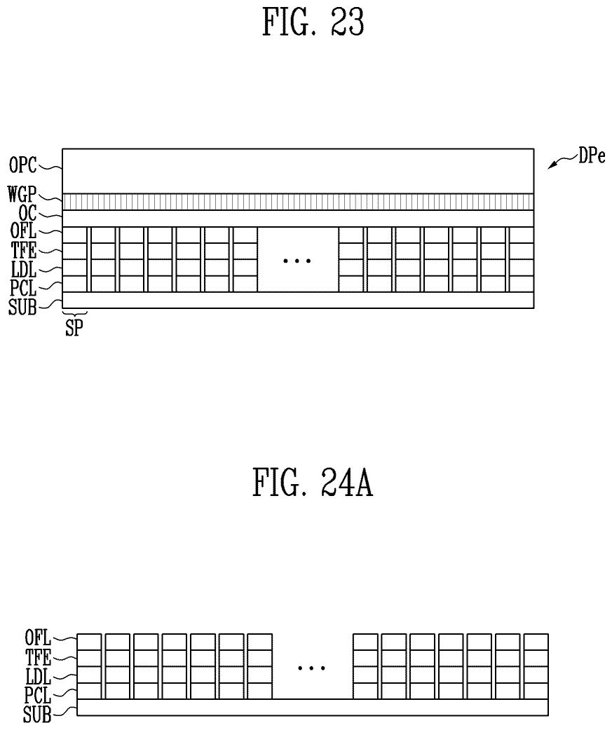

FIG. 23 is a cross-sectional view illustrating a display panel of a display device, according to an embodiment.

Referring to FIG. 23, a display panel DPe in which a wire grid polarizing layer (e.g., a wire grid polarizer) WGP is included between the light path conversion unit OPC and the overcoat layer OC is shown. The wire grid polarizing layer WGP is a polarizing layer having a nano size of a metal pattern. When light is incident on the wire grid polarizing layer WGP, a polarization component (e.g., S polarization) parallel to a metal pattern is reflected, and a polarization component (e.g., P polarization) perpendicular to the metal pattern is transmitted. By placing the wire grid polarizing layer WGP under the light path conversion unit OPC, a characteristic of light transmitted to the light path conversion unit OPC may be improved.

In FIG. 23, an embodiment in which the wire grid polarizing layer WGP is formed on the overcoat layer OC and the light path conversion unit OPC is formed on the wire grid polarizing layer WGP is shown. However, the present disclosure is not limited thereto.

According to an embodiment, the cover window CW may be interposed between the overcoat layer OC and the wire grid polarizing layer WGP. In another embodiment, the cover window CW may be interposed between the wire grid polarizing layer WGP and the light path conversion unit OPC. In another embodiment, the cover window CW may be disposed on the light path conversion unit OPC.

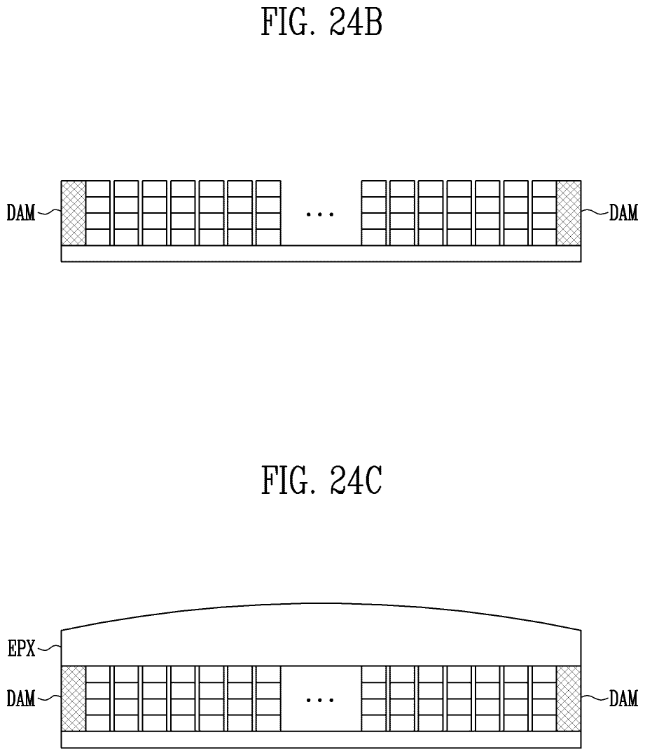

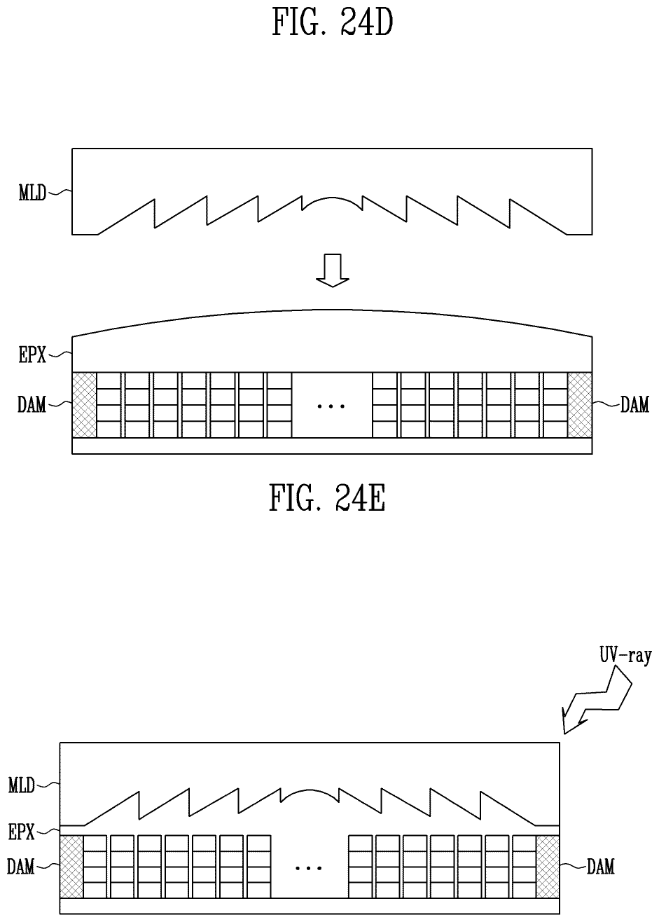

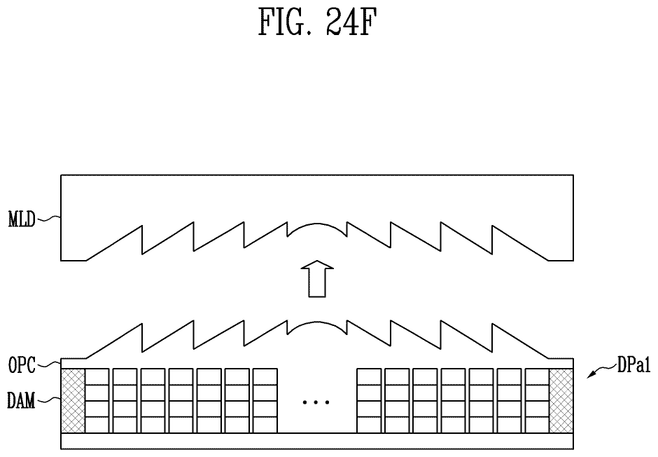

FIGS. 24A through 24F are diagrams illustrating a method of manufacturing the display panel shown in FIG. 16, according to an embodiment.

Referring to FIG. 24A, the pixel circuit layer PCL, the light emitting element layer LDL, the encapsulation layer TFE, and the optical functional layer OFL are sequentially formed on the substrate SUB. In other words, the pixel structure layer is formed on the substrate SUB. Referring to FIG. 24B, a dam DAM may be formed around the pixel structure layer, or in other words, around the display area in which the sub-pixels are included. The dam DAM may be used to maintain a stack form of the sub-pixels in a process of forming the light path conversion unit OPC1 on the pixel structure layer. The dam DAM may be formed to surround (e.g., around a periphery of) the display area formed of the sub-pixels.

Referring to FIG. 24C, thereafter, the resin layer EPX may be formed on the dam DAM and the pixel structure layer. The resin layer EPX may include an epoxy resin. However, the material forming the resin layer is not limited thereto.

Referring to FIG. 24D, the mold MLD having the intaglio pattern of the Fresnel lens may be pressed on the resin layer EPX. Accordingly, the upper surface of the resin layer EPX is transformed into the shape of the Fresnel lens. At this time, a portion of pressure transferred from the mold MLD may be transferred to a lower portion of the resin layer EPX. As shown in FIG. 24D, the dam DAM formed to surround (e.g., around a periphery of) the display area formed of the sub-pixels resists the pressure transferred from the resin layer EPX. Accordingly, even though pressure is transferred to the lower portion of the resin layer EPX, the pixel structure layer surrounded (e.g., around a periphery thereof) by the dam DAM may maintain the stack form of the sub-pixels.

Referring to FIG. 24E, the resin layer EPX may be cured by irradiating ultraviolet rays in a state in which the mold MLD is pressed on the resin layer EPX. Thereafter, the mold MLD is separated from the resin layer as shown in FIG. 24F. The separated resin layer becomes the light path conversion unit OPC implemented with the Fresnel lens having a pattern corresponding to the pattern of the mold MLD.

Referring to FIGS. 24A and 24B, after the pixel circuit layer PCL, the light emitting element layer LDL, the encapsulation layer TFE, and the optical functional layer OFL are sequentially formed on the substrate SUB, the dam DAM is formed, but the present disclosure is not limited thereto. For example, the dam DAM may be formed on the substrate SUB, and then the pixel circuit layer PCL, the light emitting element layer LDL, the encapsulation layer TFE, and the optical functional layer OFL may be sequentially formed.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display panel comprising:
a substrate;
a pixel structure layer on the substrate, and comprising a plurality of sub-pixels; and
a light path conversion unit on the pixel structure layer, and configured to convert a path of light generated from the pixel structure layer.

2. The display panel according to claim 1, wherein the light path conversion unit is configured to converge the light generated from the pixel structure layer.

3. The display panel according to claim 2, wherein the light path conversion unit comprises a Fresnel lens on the pixel structure layer.

4. The display panel according to claim 3, wherein the Fresnel lens comprises an epoxy resin.

5. The display panel according to claim 2, wherein the light path conversion unit comprises a spherical lens or an aspherical lens on the pixel structure layer.

6. The display panel according to claim 1, wherein the light path conversion unit is configured to change a progress direction of the light generated from the pixel structure layer.

7. The display panel according to claim 6, wherein the light path conversion unit comprises a reflective layer.

8. The display panel according to claim 7, wherein the reflective layer has a flat surface.

9. The display panel according to claim 7, wherein the reflective layer has a curved surface.

10. The display panel according to claim 1, further comprising:
a protective layer on the light path conversion unit.

11. The display panel according to claim 1, further comprising:
a cover window between the pixel structure layer and the light path conversion unit.

12. The display panel according to claim 11, further comprising:
a polarizing film layer between the cover window and the light path conversion unit.

13. The display panel according to claim 1, further comprising:
a wire grid polarizing layer between the pixel structure layer and the light path conversion unit.

14. The display panel according to claim 1, further comprising:
a dam surrounding the pixel structure layer.

15. The display panel according to claim 1, wherein the pixel structure layer comprises:
a pixel circuit layer on the substrate;
a light emitting element layer on the pixel circuit layer; and
an optical functional layer on the light emitting element layer.

16. The display panel according to claim 15, wherein:
the pixel circuit layer comprises at least one transistor;
the light emitting element layer comprises an anode electrode, a light emitting structure, and a cathode electrode; and
the optical function layer comprises a color filter layer and a lens array.

17. A display system comprising:
a receiving case; and
at least one display panel in the receiving case,
wherein the at least one display panel comprises:
a substrate;
a pixel structure layer on the substrate, and comprising a plurality of sub-pixels; and
a light path conversion unit on the pixel structure layer, and configured to convert a path of light generated from the pixel structure layer.

18. The display system according to claim 17, further comprising:
at least one lens in the receiving case to receive light of which a path is changed by the light path conversion unit.

19. The display system according to claim 17, wherein the light path conversion unit is configured to converge the light generated from the pixel structure layer.

20. The display system according to claim 19, wherein the light path conversion unit comprises a Fresnel lens on the pixel structure layer.

21. The display system according to claim 19, wherein the light path conversion unit comprises a spherical lens or an aspherical lens on the pixel structure layer.

22. The display system according to claim 17, wherein the light path conversion unit is configured to change a progress direction of the light generated from the pixel structure layer.

23. The display system according to claim 22, wherein the light path conversion unit comprises a reflective layer.

24. The display system according to claim 23, wherein the reflective layer has a flat surface.

25. The display system according to claim 23, wherein the reflective layer has a curved surface.
